(19) United States
(12) Patent Application Publication
(10) Pub. No.: US 2026/0136581 A1
(43) Pub. Date: May 14, 2026

(54) FIELD EFFECT TRANSISTOR AND METHOD OF MANUFACTURING THE SAME

(71) Applicant: Samsung Electronics Co., Ltd., Suwon-si (KR)

(72) Inventors: Minseok YOO, Suwon-si (KR); Changhyun KIM, Suwon-si (KR); Eunji YANG, Suwon-si (KR); Hyunmi LEE, Suwon-si (KR)

(73) Assignee: Samsung Electronics Co., Ltd., Suwon-si (KR)

(21) Appl. No.: 19/242,346

(22) Filed: Jun. 18, 2025

(30) Foreign Application Priority Data
Nov. 12, 2024 (KR) 10-2024-0160491

(51) Int. Cl. H10D 30/47; H10D 30/01

(52) U.S. Cl. CPC H10D 30/481; H10D 30/017

(57) ABSTRACT

A field effect transistor includes a plurality of horizontal channels spaced apart from each other in a second direction perpendicular to a substrate between a source electrode and a drain electrode spaced apart from each other in a first direction. A vertical channel connecting two horizontal channels adjacent to each other in the second direction is in at least one vertical gap between adjacent horizontal channels. The vertical channel extends in the first direction between the source electrode and the drain electrode. A first gate electrode faces the plurality of horizontal channels and the vertical channel. A gate insulating layer insulates the first gate electrode from the source electrode, the drain electrode, the plurality of horizontal channels, and the vertical channel. The plurality of horizontal channels and the vertical channel each independently include a two-dimensional (2D) semiconductor material.

### CROSS-REFERENCE TO RELATED APPLICATION

This application is based on and claims priority under 35 U.S.C. § 119 to Korean Patent Application No. 10-2024-0160491, filed on Nov. 12, 2024, in the Korean Intellectual Property Office, the disclosure of which is incorporated by reference herein in its entirety.

### BACKGROUND

### 1. Field

The inventive concepts relate to field effect transistors including multi-bridge channels and methods of manufacturing the field effect transistors.

### 2. Description of the Related Art

Field effect transistors are semiconductor devices with an electrical switching function and are employed in various integrated circuit (IC) devices including memory devices, driving ICs, logic devices, etc. In order to increase the degree of integration of IC devices, the size of field effect transistors has been rapidly reduced, and research has been conducted to maintain the performance of field effect devices while reducing the size of field effect transistors.

In a field effect transistor, the flow of current through a channel is controlled according to a voltage applied to a gate electrode. The larger the contact area between the gate electrode and the channel, the greater the power efficiency of the field effect transistor. As semiconductor processes are becoming more refined, the size of the field effect transistor is reduced, and the length of the channel decreases.

### SUMMARY

Some example embodiments include a field effect transistor capable of securing a contact area between a gate electrode and a channel, and methods of manufacturing the same. Such a field effect transistor may exhibit reduced contact area between the gate electrode and the channel of the field effect transistor with reduced, minimized, or prevented occurrence of problems due to a short channel effect, such as threshold voltage variation, carrier velocity saturation, and deterioration of subthreshold characteristics. Accordingly, such a field effect transistor and methods of manufacturing same according to some example embodiments may overcome the short channel effect while simultaneously effectively reducing a channel length of the field effect transistors.

Some example embodiments include a field effect transistor including multi-bridge channels and a method of manufacturing the same.

Additional aspects will be set forth in part in the description which follows and, in part, will be apparent from the description, or may be learned by practice of the presented embodiments of the inventive concepts.

According to some example embodiments of the inventive concepts, a field effect transistor may include a source electrode and a drain electrode on a substrate, the source electrode and the drain electrode spaced apart from each other in a first direction parallel to an upper surface of the substrate, a plurality of horizontal channels between the source electrode and the drain electrode, the plurality of horizontal channels spaced apart from each other in a second direction perpendicular to the upper surface of the substrate, a vertical channel in at least one vertical gap defined between two horizontal channels of the plurality of horizontal channels adjacent to each other in the second direction, such that the vertical channel connects the two horizontal channels to each other in the second direction, the vertical channel extending in the first direction between the source electrode and the drain electrode, a first gate electrode facing the plurality of horizontal channels and the vertical channel, and a gate insulating layer insulating the first gate electrode from each of the source electrode, the drain electrode, the plurality of horizontal channels, and the vertical channel. The plurality of horizontal channels and the vertical channel may each independently include a two-dimensional (2D) semiconductor material.

In some example embodiments, the vertical channel may not penetrate the plurality of horizontal channels.

In some example embodiments, in a cross-section perpendicular to the first direction, the first gate electrode may at least partially surround the plurality of horizontal channels and the vertical channel.

In some example embodiments, the field effect transistor may further include a plurality of bridges supported by the source electrode and the drain electrode and spaced apart from each other in the second direction. In a cross-section perpendicular to the first direction, the plurality of horizontal channels may include a horizontal channel in a closed-loop shape surrounding a separate bridge of the plurality of bridges.

In some example embodiments, each bridge of the plurality of bridges may include an insulating layer.

In some example embodiments, the insulating layer may include at least one of low-doped silicon, SiO₂, Al₂O₃, HfO₂, Si₃N₄, ZrO, HfZrO, or HfAlO.

In some example embodiments, each bridge of the plurality of bridges may include a second gate electrode, and an insulating layer surrounding the second gate electrode, the insulating layer between the plurality of horizontal channels and the second gate electrode.

In some example embodiments, the vertical channel may not penetrate the plurality of bridges.

In some example embodiments, the plurality of horizontal channels and the vertical channel may include a same material.

In some example embodiments, the 2D semiconductor material may have a multilayer structure.

In some example embodiments, the 2D semiconductor material may include graphene, black phosphorus, phosphorene, or transition metal dichalcogenide (TMD).

In some example embodiments, the TMD may include one metal element selected from the group consisting of Mo, W, Nb, V, Ta, Ti, Zr, Hf, Tc, Re, Cu, Ga, In, Sn, Ge, and Pb, and one chalcogen element selected from the group consisting of S, Se, and Te.

In some example embodiments, the 2D semiconductor material may be doped with a particular conductive dopant.

According to some example embodiments of some example embodiments, a method of manufacturing a field effect transistor may include forming, on a substrate, a source electrode, a drain electrode, and a plurality of bridges, the plurality of bridges spaced apart from each other in a direction perpendicular to an upper surface of the substrate, the plurality of bridges between the source electrode and the drain electrode, forming a channel based on supplying catalyst particles and a precursor of a channel material to the plurality of bridges, forming a plurality of horizontal channels based on depositing the channel material on surfaces of the plurality of bridges from the precursor, and forming a vertical channel connecting two horizontal channels adjacent to each other in at least one vertical gap of a plurality of vertical gaps between adjacent horizontal channels of the plurality of horizontal channels based on reacting the catalyst particles with the precursor of the channel material, depositing a gate insulating layer on the channel, and depositing a gate electrode on the gate insulating layer.

In some example embodiments, the forming of channel may include forming a catalyst particle layer including the catalyst particles between adjacent bridges of the plurality of bridges, and placing a stack structure including the substrate into a deposition chamber and supplying the precursor of the channel material.

In some example embodiments, the forming of the catalyst particle layer may include coating a catalyst solution including the catalyst particles on the plurality of bridges, and at least partially drying the catalyst solution.

In some example embodiments, the forming of the channel may further include forming a liquid intermediate based on reacting the precursor of the channel material with the catalyst particles, and forming the vertical channel from the liquid intermediate.

In some example embodiments, the channel material may include TMD.

In some example embodiments, the catalyst particles may include NaCl, KI, or NaI.

In some example embodiments, the catalyst particles may include Na₂Mo₂O₇ or Na₂MoO₄.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a perspective view of a field effect transistor according to some example embodiments;

FIG. 2 is a cross-sectional view taken along line Y1-Y1′ of the field effect transistor of FIG. 1 according to some example embodiments;

FIG. 3 is a cross-sectional view taken along line X1-X1′ of the field effect transistor of FIG. 1 according to some example embodiments;

FIG. 4 is a diagram for explaining an effective channel width of the field effect transistor shown in FIGS. 1 to 3 and a corresponding gating effect according to some example embodiments;

FIG. 5 is a graph showing an effect of expanding an effective channel width according to a vertical gap and a channel width when a vertical channel is applied and when not applied according to some example embodiments;

FIG. 6 is a graph showing a gating effect according to a vertical gap and a channel width when a vertical channel is applied and when not applied according to some example embodiments;

FIG. 7 illustrates a first cross-section of a field effect transistor according to some example embodiments;

FIG. 8 illustrates a second cross-section of a field effect transistor according to some example embodiments;

FIGS. 9A, 9B, 9C, 9D, 9E, 9F, 9G, 9H, 9I, and 9J are diagrams illustrating a method of manufacturing a field effect transistor according to some example embodiments;

FIG. 10 illustrates a transmission electron microscopy (TEM) image obtained by forming a vertical channel connecting two horizontal channels adjacent to each other between a plurality of horizontal channels through a metal organic chemical vapor deposition (MOCVD) method according to some example embodiments;

FIGS. 11A, 11B, 11C, 11D, 11E, 11F, 11G, and 11H are diagrams illustrating a method of manufacturing a field effect transistor, according to some example embodiments;

FIG. 12 is a schematic block diagram of a display driver integrated circuit (DDI) including a field effect transistor and a display device including the DDI, according to some example embodiments;

FIG. 13 is a circuit diagram of a complementary metal oxide semiconductor (CMOS) inverter including a field effect transistor, according to some example embodiments;

FIG. 14 is a circuit diagram of a CMOS static random-access memory (SRAM) device including a field effect transistor, according to some example embodiments;

FIG. 15 is a circuit diagram of a CMOS NAND circuit including a field effect transistor, according to some example embodiments;

FIG. 16 is a block diagram of an electronic system including a field effect transistor, according to some example embodiments; and

FIG. 17 is a block diagram of an electronic system including a field effect transistor, according to some example embodiments.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, field effect transistors and methods of manufacturing the field effect transistors according to some example embodiments will be described in detail with reference to the accompanying drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” a component, another component may be further included, rather than excluding the existence of the other component, unless otherwise described. Sizes or thicknesses of components in the drawings may be arbitrarily exaggerated for convenience of explanation. Further, when a certain material layer is described as being arranged on a substrate or another layer, the material layer may be in contact with the other layer, or there may be a third layer between the material layer and the other layer. In the following example embodiments, materials constituting each layer are provided merely as an example, and other materials may also be used.

Moreover, the terms “part,” “module,” etc. refer to a unit processing at least one function or operation, and may be implemented by a hardware, a software, or a combination thereof.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail. Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of the terms “a” and “an” and “the” and similar referents are to be construed to cover both the singular and the plural.

Also, operations of all methods described herein may be performed in any suitable order unless otherwise indicated herein or otherwise clearly contradicted by context. The use of any and all exemplary languages (e.g., “such as”) provided herein, are intended merely to better illuminate the technical ideas and does not pose a limitation on the scope of rights unless otherwise claimed.

As the inventive concepts allow for various changes and numerous various example embodiments, some example embodiments will be illustrated in the drawings and described in detail in the written description. However, this is not intended to limit the inventive concepts to particular modes of practice, and it is to be appreciated that all modifications, equivalents, and substitutes that do not depart from the spirit and technical scope of the inventive concepts are encompassed in the inventive concepts. In describing the inventive concepts, when it is determined that the specific description of the known related art unnecessarily obscures the gist of the inventive concepts, the detailed description thereof will be omitted.

A portion of a layer, film, region, plate, or the like described as being “on” or “above” another portion as used herein, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

In order to clearly explain the present inventive concepts in the drawings, parts that are not related to the description are omitted, and similar parts are given similar reference numerals throughout the specification. In the methods described herein, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

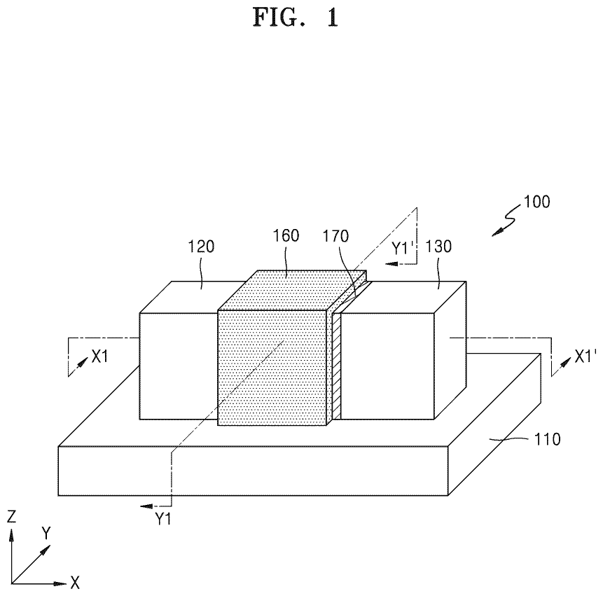

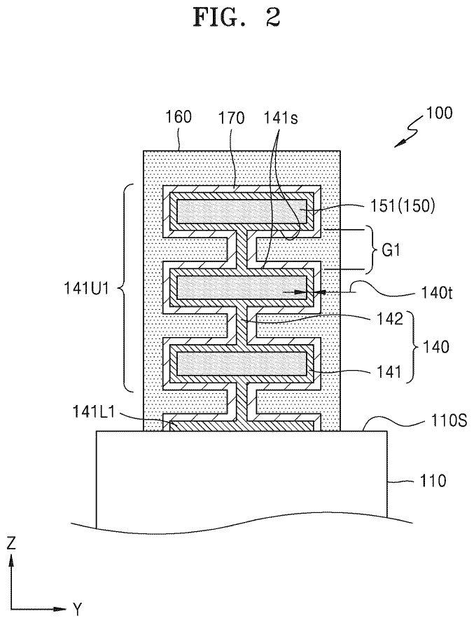

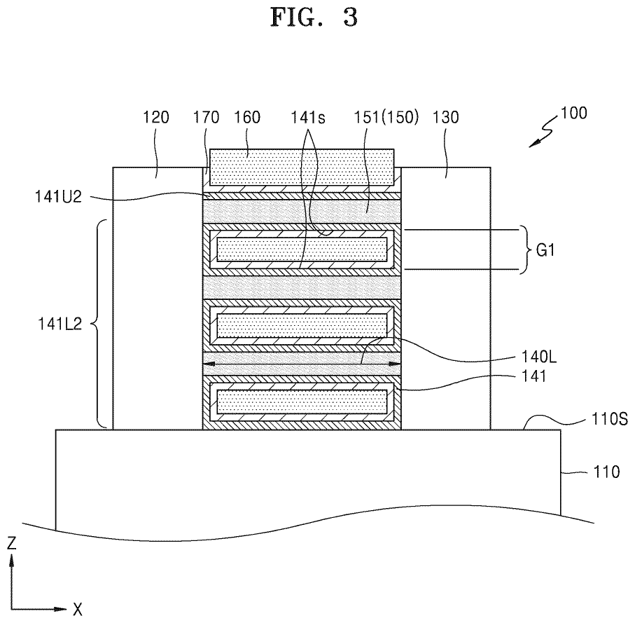

FIG. 1 is a perspective view of a field effect transistor according to some example embodiments. FIG. 2 is a cross-sectional view taken along line Y1-Y1′ of the field effect transistor of FIG. 1. FIG. 3 is a cross-sectional view taken along line X1-X1′ of the field effect transistor of FIG. 1.

Referring to FIGS. 1 to 3, a field effect transistor 100 according to some example embodiments may include a substrate 110, a source electrode 120 and a drain electrode 130 which are spaced apart from each other on the substrate 110 (e.g., in a first direction parallel to the substrate 110), a channel 140 connected between the source electrode 120 and the drain electrode 130, a gate electrode (first gate electrode) 160 facing the channel 140, and a gate insulating layer 170. The channel 140 may include a plurality of horizontal channels 141 between the source electrode 120 and the drain electrode 130 and spaced apart from each other in a direction perpendicular to the substrate 110, and a vertical channel 142 provided on at least one vertical gap of a plurality of vertical gaps G1 between adjacent horizontal channels 141 of the plurality of horizontal channels 141 and connecting two horizontal channels 141 adjacent to each other in a direction perpendicular to the substrate 110. The gate insulating layer 170 insulates the first gate electrode 160 from the source electrode 120, the drain electrode 130, and the channel 140. The first gate electrode 160 faces the channel 140 with the gate insulating layer 170 disposed therebetween. A multi-bridge channel structure may be implemented by the plurality of horizontal channels 141.

“X” and “Y” represent two orthogonal directions on a plane parallel to an upper surface 110s of the substrate 110, and “Z” represents a direction perpendicular to the substrate 110 (e.g., perpendicular to the upper surface 110s of the substrate 110). Hereinafter, a case where the source electrode 120 and the drain electrode 130 are spaced apart from each other in an X direction (first direction), and the plurality of horizontal channels 141 are spaced apart from each other in a Z direction (second direction) will be described, where the X direction (first direction) may be understood to extend parallel to an upper surface 110s of the substrate 110 and the Z direction (second direction) may be understood to extend perpendicular to the upper surface 110s of the substrate 110. FIG. 2 illustrates a cross-section (first cross-section) of the field effect transistor 100 that is perpendicular to the X direction which is the separation direction between the source electrode 120 and the drain electrode 130 and that is disposed between the source electrode 120 and the drain electrode 130. FIG. 3 shows a cross-section (second cross-section) of the field effect transistor 100 that is perpendicular to a Y direction (third direction) and crosses the source electrode 120 and the drain electrode 130.

The substrate 110 may be an insulating substrate. The substrate 110 may be a semiconductor substrate having an insulating layer formed on a surface thereof, for example, an upper surface thereof. The semiconductor substrate may include, for example, Si, Ge, SiGe, or a group III-V semiconductor material. The substrate 110 may be, for example, a silicon substrate having a silicon oxide formed on the surface thereof, but is not limited thereto.

The source electrode 120 and the drain electrode 130 are disposed to be spaced apart from each other in the first direction X (e.g., a direction parallel to the upper surface 110s of the substrate 110). The source electrode 120 and the drain electrode 130 may each include an electrode material. The electrode material may include a metal material having electrical conductivity. For example, the source electrode 120 and the drain electrode 130 may each include a metal such as magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (Hf), tantalum (Ta), tungsten (W), iridium (Ir), platinum (Pt), gold (Au), bismuth (Bi), etc., or any alloy thereof.

Referring to FIGS. 2 and 3, the channel 140 functions as a path through which current flows between the source electrode 120 and the drain electrode 130. The channel 140 may be in direct contact with each of the source electrode 120 and the drain electrode 130 (e.g., may be understood to be directly between the source electrode 120 and the drain electrode 130), and may be connectable to the source electrode 120 and the drain electrode 130 through another medium. As described above, the channel 140 may include the plurality of horizontal channels 141 and one or more vertical channels 142. Each horizontal channel 141 of the plurality of horizontal channels 141 extends in the separation direction X (first direction) between the source electrode 120 and the drain electrode 130. The horizontal channel 141 (e.g., the longitudinal axis thereof) may be parallel to an X-Y plane, but is not limited thereto. The horizontal channel 141 (e.g., the longitudinal axis thereof) may have a certain angle with respect to the X-Y plane. The plurality of horizontal channels 141 are arranged to be spaced apart from each other in the Z direction (second direction). Accordingly, the plurality of vertical gaps G1 are formed between the plurality of horizontal channels 141. For example, the plurality of horizontal channels 141 may at least partially define the plurality of vertical gaps G1 such that each separate vertical channel G1 may be defined between opposing surfaces of two adjacent horizontal channels 141 that are adjacent to each other in the second direction (Z direction). The plurality of vertical gaps G1 may be the same or may be different (e.g., in magnitude in the second direction). In some example embodiments, the plurality of vertical gaps G1 are the same (e.g., in magnitude in the second direction).

In some example embodiments, the plurality of horizontal channels 141 may include a horizontal channel in a closed loop shape in the first cross-section, that is, a cross-section perpendicular to the first direction X (e.g., the YZ plane). Referring to FIG. 2, in the first cross-section, three horizontal channels 141U1 positioned above a lowest horizontal channel 141L1 among the plurality of horizontal channels 141 have the closed loop shape. For example, between the source electrode 120 and the drain electrode 130 (e.g., in the first direction), a plurality of bridges 150 may be disposed to be spaced apart from each other in the Z direction, and each horizontal channel 141U1 may surround a separate bridge 150 of the plurality of bridges 150 in the first cross-section. Accordingly, the three horizontal channels 141U1 in the closed loop shape may be implemented in the first cross-section. In this case, the lowest horizontal channel 141L1 contacting the substrate 110 has a sheet shape.

Referring to FIG. 3, the plurality of horizontal channels 141 may have a horizontal channel in the closed loop shape in the second cross-section perpendicular to the third direction Y (e.g., the XZ plane). Three horizontal channels 141L2 positioned below an uppermost horizontal channel 141U2 among the plurality of horizontal channels 141 have the closed loop shape. For example, each horizontal channel 141L2 surrounds a space between adjacent bridges of the plurality of bridges 150 on the second cross-section, that is, the vertical gap G1. Accordingly, the three horizontal channels 141L2 in the closed loop shape may be implemented in the second cross-section. In this case, the uppermost horizontal channel 141U2 has the sheet shape. FIG. 2 and FIG. 3 illustrate the plurality of horizontal channels 141 in a rectangular closed loop shape, but the horizontal channels 141 are not limited thereto. For example, a horizontal channel 141 of the plurality of horizontal channels 141 may have a closed loop shape including a circular, elliptical, or irregular figure. Referring to FIG. 3, the plurality of horizontal channels 141 are in contact with each of the source electrode 120 and the drain electrode 130 in some example embodiments. The horizontal channels 141 in the closed loop shape are, in some example embodiments, in surface contact with each of the source electrode 120 and the drain electrode 130 to enable stable electrical connection to the source electrode 120 and the drain electrode 130.

The plurality of bridges 150 may function as a support layer for depositing a channel material in a manufacturing process to be described below. The thickness of the plurality of bridges 150 may be, for example, greater than 0 and less than or equal to 100 nm. For example, the thickness of the bridges 150 may be greater than 0 and less than or equal to 20 nm. In some example embodiments, each of the plurality of bridges 150 may include an insulating layer 151. The insulating layer 151 may include at least one of, for example, low-doped silicon, SiO₂, Al₂O₃, HfO₂, Si₃N₄, ZrO, HfZrO, or HfAlO. The shape of the horizontal channel 141 may be determined according to the shape of the plurality of bridges 150.

The vertical channel 142 is provided on at least one vertical gap G1 of the plurality of vertical gaps G1 to connect the two horizontal channels 141 adjacent to each other in the Z direction. For example, a vertical channel 142 may be in a vertical gap G1 defined between two horizontal channels 141 of the plurality of horizontal channels 141 adjacent to each other in the second direction (Z direction), such that the vertical channel 142 connects the two horizontal channels 141 to each other in the second direction (Z direction). FIG. 2 illustrates the vertical channel 142 extending between adjacent horizontal channels 141 in parallel with the Z direction, but the vertical channel 142 is not limited thereto. The vertical channel 142 may have an angle of 10 degrees to 90 degrees with respect to the Y direction. Although not shown in FIG. 3, the vertical channel 142 may extend in the separation direction X (first direction) between the source electrode 120 and the drain electrode 130 such that both ends (e.g., opposite ends) thereof in the X direction may be connected (e.g., directly connected) to the source electrode 120 and the drain electrode 130, respectively. The extension direction of the vertical channel 142 may be parallel to the X direction, and may have a certain angle in the X direction. In the first cross-section, the vertical gaps G1 may be formed between the horizontal channels 141 (e.g., between opposing surfaces 141s of adjacent horizontal channels 141), and the vertical channel 142 may be provided in at least one of the vertical gaps G1. In some example embodiments, the vertical channel 142 does not penetrate the plurality of bridges 150, and connects the two horizontal channels 141 adjacent to each other in the vertical gaps G1.

In some example embodiments, the vertical channels 142 are provided in all of the plurality of vertical gaps G1. In FIG. 2, the plurality of vertical channels 142 have the same positions in the Y direction, but this is an example and example embodiments are not limited thereto. At least one vertical channel 142 of the plurality of vertical channels 142 may have a position different from the others in the Y direction. In addition, at least one vertical channel 142 of the plurality of vertical channels 142 may extend between respective adjacent horizontal channels 141 at an angle different from the others (e.g., the other vertical channels 142) in the Y direction. In addition, at least one vertical channel 142 of the plurality of vertical channels 142 may extend between respective adjacent horizontal channels 141 at an angle different from the others (e.g., the other vertical channels 142) in the X direction.

For example, the thickness 140t of the channel 140, that is, the thickness of each of the horizontal channel 141 and the vertical channel 142 (e.g., in the first direction, or X direction) may be less than or equal to 20 nm. For example, the thickness 140t of the channel 140 may be less than or equal to 10 nm. For example, the thickness 140t of the channel 140 may be less than or equal to 5 nm. For example, the thickness 140t of the channel 140 may be less than or equal to 1 nm. The thickness 140t of the channel 140 may be equal to or greater than 0.01 nm. The thickness 140t of the channel 140 may be equal to or greater than 0.1 nm. For example, a distance between the source electrode 120 and the drain electrode 130 (e.g., in the first direction, or X direction) may be, for example, may be less than or equal to 100 nm. For example, a distance (e.g., channel length 140L distance) between the source electrode 120 and the drain electrode 130 may be, for example, less than or equal to 50 nm. For example, a distance between the source electrode 120 and the drain electrode 130 may be, for example, less than or equal to 20 nm. Such a distance may be a distance of a channel length 140L.

The channel 140 may include the channel material. The field effect transistor 100 according to some example embodiments may employ a two-dimensional (2D) semiconductor material as the channel material. In some example embodiments, the plurality of horizontal channels 141 and the vertical channel(s) 142 of the channel 140 may each independently include a channel material, which may be a two-dimensional (2D) semiconductor material. In some example embodiments, the plurality of horizontal channels 141 and the vertical channel(s) 142 of the channel 140 may be defined by separate portions of a single, unitary piece of channel material which may be or include the two-dimensional (2D) semiconductor material. The 2D semiconductor material refers to a semiconductor material having a 2D crystal structure, and may have a monolayer or multilayer structure. Each layer constituting such a 2D semiconductor material may have the thickness of an atomic level. The 2D semiconductor material has excellent electrical characteristics, and maintains high mobility even when its thickness (e.g., thickness 140t) is reduced to nano scale, and thus may be applied to various devices. The 2D semiconductor material may include graphene, black phosphorous, or transition metal dichalcogenide (TMD). The TMD may include one metal element selected from the group consisting of Mo, W, Nb, V, Ta, Ti, Zr, Hf, Tc, Re, Cu, Ga, In, Sn, Ge, Pb and one chalcogen element selected from the group consisting of S, Se, and Te. The 2D semiconductor material may be doped with a certain (e.g., particular) conductive type dopant.

Graphene, which is a material that has a hexagonal honeycomb structure in which carbon atoms are 2D bonded, has the advantages of high electrical mobility, excellent thermal properties, chemical stability, and a large surface area compared to silicon (Si). Also, black phosphorus is a material in which black phosphorous atoms are 2D bonded.

The TMD may include one metal element among Mo, W, Nb, V, Ta, Ti, Zr, Hf, Tc, and Re and one chalcogen element among S, Se, and Te. The TMD may be expressed, for example, as MX₂, where M represents a transition metal and X represents a chalcogen element. For example, M may be Mo, W, Nb, V, Ta, Ti, Zr, Hf, Tc, Re, etc., and X may be S, Se, Te, etc. Thus, for example, the TMD may include MoS₂, MoSe₂, MoTe₂, WS₂, WSe₂, WTe₂, ZrS₂, ZrSe₂, HfS₂, HfSe₂, NbSe₂, or ReSe₂. In some example embodiments, the TMD may not be expressed as MX₂. casein some example embodiments, for example, the TMD may include CuS, which is a compound of Cu, a transition metal, and S, a chalcogen element. Meanwhile, the MD may be a chalcogenide material including a non-transition metal. The non-transition metal may include, for example, Ga, In, Sn, Ge, Pb, etc. In this case, the TMD may include a compound of non-transition metal such as Ga, In, Sn, Ge, and Pb and a chalcogen element such as S, Se, and Te. For example, the TMD may include SnSe₂, GaS, GaSe, GaTe, GeSe, In₂Se₃, InSnS₂, etc.

As described above, the TMD may include one metal element among Mo, W, Nb, V, Ta, Ti, Zr, Hf, Tc, Re, Cu, Ga, In, Sn, Ge, and Pb and one chalcogen element among S, Se, and Te. However, the materials mentioned above are examples, and other materials may be used as the TMD material.

The 2D semiconductor material may be doped with p-type dopant or n-type dopant to control mobility. Here, the p-type dopant and n-type dopant may be, for example, p-type dopant and n-type dopant used in graphene or carbon nanotube (CNT). The p-type dopant or n-type dopant may be doped by using ion implantation or chemical doping.

As shown in FIGS. 2 and 3, each vertical channel 142 may not penetrate the plurality of horizontal channels 141. In other words, the vertical channel 142 may not penetrate the plurality of bridges 150. The plurality of horizontal channels 141 and the plurality of vertical channels 142 may include the same channel material. This means that the plurality of horizontal channels 141 and the plurality of vertical channels 142 may be formed simultaneously in a semiconductor process of forming the channel 140 and may be defined by separate portions of a single, unitary piece of channel material. Therefore, the manufacturing process of the field effect transistor 100 may be simplified, and the channel 140 may be stably formed because a crystal structure of the channel material is continuous in a connection portion where the horizontal channel 141 and the vertical channel 142 are connected to each other.

The first gate electrode 160 faces the channel 140 with the gate insulating layer 170 disposed therebetween. The gate insulating layer 170 may be formed on outer surfaces of a plurality of horizontal channels 141. The gate insulating layer 170 may be formed on surfaces of the plurality of vertical channels 142. The gate insulating layer 170 may insulate the channel 140 from the first gate electrode 160 (e.g., isolate the channel 140 from direct contact with the first gate electrode 160 and at least partially electrically insulate the channel 140 from the first gate electrode 160) and suppress (e.g., reduce, minimize, or prevent) leakage current (e.g., leakage current between the channel 140 and the first gate electrode 160). The gate insulating layer 170 may include a ferroelectric material. The ferroelectric material has a spontaneous electric dipole due to non-centrosymmetric charge distribution within a unit cell in a crystallized material structure, that is, spontaneous polarization. Therefore, the ferroelectric material has remnant polarization due to a dipole even in the absence of an external electric field. In addition, a direction of polarization may be switched in a domain unit by the external electric field. Such a ferroelectric material may include, for example, an oxide including at least one selected from Hf, Si, Al, Zr, Y, La, Gd, and Sr, but this is an example. In addition, if necessary, the ferroelectric material may further include a dopant.

When the gate insulating layer 170 includes the ferroelectric material, the field effect transistor 100 may be applied as, for example, a logic device or a memory device. When the gate insulating layer 170 includes the ferroelectric material, a subthreshold swing (SS) may be lowered due to a negative capacitance effect, and thus, performance may be improved while reducing the size of the field effect transistor 100.

The gate insulating layer 170 may have a multilayer structure including a high-k material and a ferroelectric material. The gate insulating layer 170 may include a charge trapping layer such as silicon nitride, and thus the field effect transistor 100 may operate as a memory transistor having memory characteristics.

The first gate electrode 160 may include an electrode material. The electrode material may include, for example, a metal material or a conductive oxide. The metal material may include, for example, Au, Ti, TiN, TaN, W, Mo, WN, Pt or Ni. The conductive oxide may include, for example, indium tin oxide (ITO), indium zinc oxide (IZO), etc. The first gate electrode 160 may include the same material as the source electrode 120 and the drain electrode 130.

In the first cross-section, the first gate electrode 160 surrounds the plurality of horizontal channels 141 and the plurality of vertical channels 142 with the gate insulating layer 170 disposed therebetween. Accordingly, the field effect transistor 100 having a so-called gate all around (GAA) structure may be implemented. Furthermore, in the relationship between the plurality of vertical channels 142 and the first gate electrode 160, a dual gating structure may be obtained in which the first gate electrodes 160 are disposed on both sides (e.g., opposite sides) of the plurality of vertical channels 142. Therefore, according to the field effect transistor 100 of some example embodiments, a greater (e.g., improved) gating effect may be implemented.

In increasing the degree of integration of a semiconductor device including the field effect transistor 100, a short channel effect due to a decrease in the channel length (e.g., distance between the source and drain electrodes) may become a problem. The short channel effect means the performance limit that appears when the channel length is shortened, and are, for example, a phenomenon such as threshold voltage variation, carrier velocity saturation, and deterioration of sub-threshold characteristics. The short channel effect is known to be related to a channel thickness. As the channel thickness becomes thinner, the minimum channel length that may be implemented becomes shorter. Therefore, when an ultra-small transistor is to be implemented to increase integration, the channel length may be effectively reduced by reducing the channel thickness. On the other hand, in the case where the channel thickness is reduced with a typical bulk material, for example, a silicon-based material, when the thickness is reduced to several nanometers or less, the number of carriers inside the silicon decreases, which causes a problem of lowering electron mobility.

In the field effect transistor 100 of some example embodiments, the channel 140 includes the 2D semiconductor material, and thus, high electron mobility may be maintained even though the thickness 140t of the channel 140 is reduced to several nanometers or less. In addition, the field effect transistor 100 according to some example embodiments may have a multi-bridge structure in which both sides of the channel 140 are in contact with the source electrode 120 and the drain electrode 130 and are stacked to be spaced apart in a direction away from the substrate 110. A channel with a multi-bridge structure may reduce the short channel effect and reduce the area occupied by source/drain electrodes, and thus, the channel is advantageous for high integration. In addition, the channel 140 may maintain uniform source/drain junction capacitance regardless of a position of the channel 140, and thus, the channel 140 with a multi-bridge structure may be applied as a higher-speed and higher-reliability device. FIG. 2 illustrates three multi-bridge channels, but this is exemplary, and the field effect transistor 100 of some example embodiments may include four or more stacked multi-bridge channels. As a non-limiting example, the field effect transistor 100 may include ten or less multi-bridge channels.

In addition, the field effect transistor 100 according to some example embodiments may have a GAA structure in which the first gate electrode 160 surrounds four surfaces of the channel 140, and thus the current may be adjusted more precisely, and higher power efficiency (e.g., improved power consumption efficiency) may be obtained. The field effect transistor 100 according to some example embodiments may further increase the area in which a gate electrode and a channel contact each other (e.g., increase the contact area between the gate electrode and the channel). Therefore, the field effect transistor 100 according to some example embodiments may reduce power consumption and improve performance.

Furthermore, the field effect transistor 100 according to some example embodiments employs the channel 140 including the plurality of horizontal channels 141 and a vertical channel 142 connecting two horizontal channels 141 adjacent to each other in at least one of the plurality of vertical gaps G1 between adjacent horizontal channels 141 of the plurality of horizontal channels 141. The vertical channel 142 forms the dual gating structure with the first gate electrode 160. In general, because a bridge gap, that is, the vertical gap G1, is larger than the thickness of a bridge, the channel 140 including the vertical channel 142 may provide an effective channel width greater than that of a channel of a typical GAA structure. Therefore, a higher on-current characteristic, which is a main operation specification of the field effect transistor 100, may be implemented. In addition, the field effect transistor 100 according to some example embodiments may have higher gate controllability because it has the GAA structure as a whole and simultaneously the dual gating structure from the perspective of the vertical channel 142.

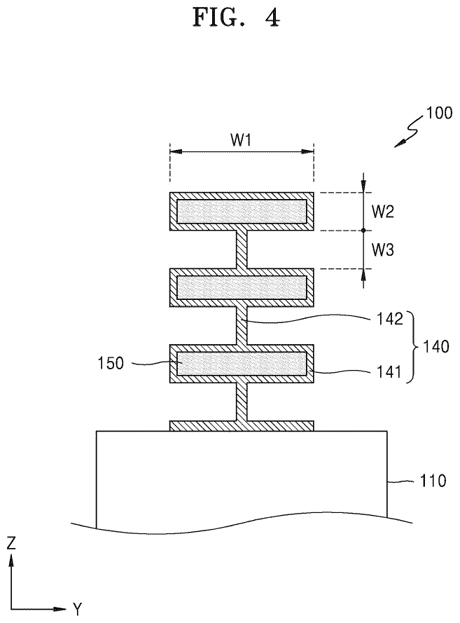

FIG. 4 is a diagram for explaining an effective channel width of the field effect transistor 100 shown in FIGS. 1 to 3 and a corresponding gating effect according to some example embodiments. In the case of a typical GAA structure (a GAA structure without the vertical channel 142), when the effective channel width provided by the closed-loop three horizontal channels 141 and one sheet type horizontal channel 141 is W_{W/O-VC}, the area of the channel 140 facing the first gate electrode 160 is A_{W/O-VC}, the width of a horizontal channel 141 in the Y direction (e.g., perpendicular to the first and second directions and parallel to the upper surface 110s of the substrate 110) is W1, a distance between opposite surfaces of a horizontal channel 141 (e.g., a horizontal channel having a closed-loop shape) in the second direction (Z direction) is W2, and the length of the channel 140 in the X direction is a,

W_{W/O-VC}=7×W1+6×W2

A_{W/O-VC}=a×W_{W/O-VC}=a(7×W1+6×W2)

In some example embodiments, in the case of a GAA structure including the vertical channel 142, the vertical channel 142 has a dual gating structure in which the vertical channel 142 faces the first gate electrode 160 on both sides in the Y direction. Therefore, in this case, when the effective channel width provided by the three closed-loop horizontal channels 141, one sheet type horizontal channel 141, and the three vertical channels 142 is W_{W-VC}, the channel width of a horizontal channel 141 in the Y direction (e.g., perpendicular to the first and second directions and parallel to the upper surface 110s of the substrate 110) is W1, a distance between opposite surfaces of a horizontal channel 141 (e.g., a horizontal channel having a closed-loop shape) in the second direction (Z direction) is W2, the thickness of a vertical channel 142 between opposing surfaces of adjacent horizontal channel 141 in the second direction (Z direction) is W3, and the area of the channel 140 facing the first gate electrode 160 is A_{W-VC},

W_{W-VC}=7×W1+6×W2+3×W3

A_{W-VC}=a(7×W1+6×W2)+2a(3×W3)

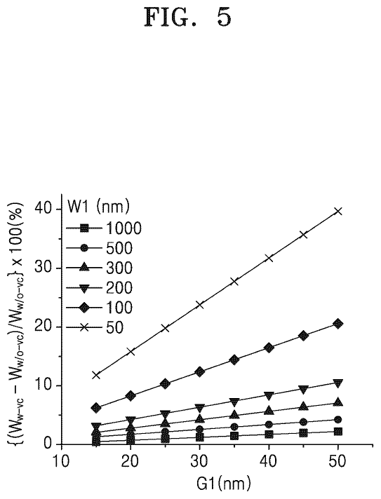

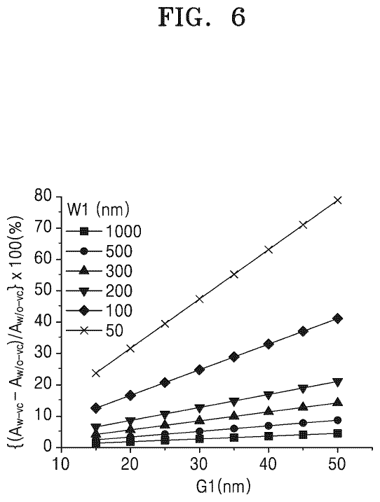

FIG. 5 is a graph showing an effect of expanding an effective channel width according to the vertical gap G1 and a channel width W1 when the vertical channel 142 is applied and when not applied according to some example embodiments. FIG. 6 is a graph showing a gating effect according to the vertical gap G1 and the channel width W1 when the vertical channel 142 is applied and when not applied according to some example embodiments. In FIGS. 5 and 6, W2 is 5 nm. Referring to FIGS. 5 and 6, in the case of a GAA structure including the vertical channel 142, a greater effective channel width may be provided compared to a typical GAA structure, thereby providing a greater gating effect. In particular, when the vertical channel 142 is applied to the GAA structure, the vertical channel 142 has a dual gating structure, and thus the gating effect may be increased.

The field effect transistor 100 according to some example embodiments may be applied to an electronic device requiring high performance and low power, such as mobile, display, artificial intelligence (AI), 5G communication equipment, electric device, Internet of Things (IoT), etc.

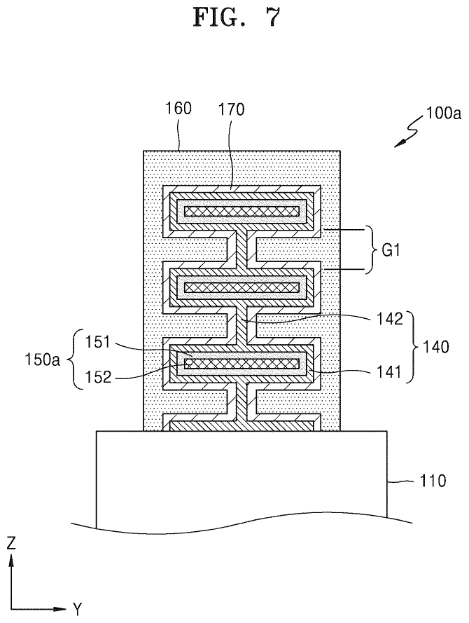

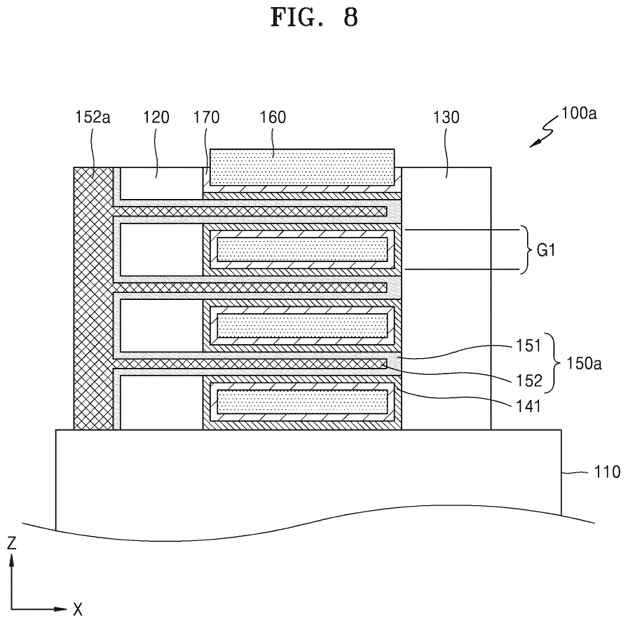

FIG. 7 illustrates a first cross-section of a field effect transistor 100a according to some example embodiments. FIG. 8 illustrates a second cross-section of the field effect transistor 100a according to some example embodiments. The field effect transistor 100a according to some example embodiments is different from the field effect transistor 100 shown in FIGS. 1 to 3 in that the field effect transistor 100a further includes a second gate electrode 152. Hereinafter, differences will be mainly described, and components performing the same function will be indicated by the same reference numerals, and redundant descriptions will be omitted.

Referring to FIGS. 7 and 8, the field effect transistor 100a according to some example embodiments may further include the second gate electrode 152. For example, each bridge of a plurality of bridges 150a may include the second gate electrode 152 and an insulating layer 151. The insulating layer 151 surrounds the second gate electrode 152 (e.g., in the YZ plane) and is disposed between a horizontal channel 141 (e.g., a horizontal channel 141 surrounding the bridge 150a in the YZ plane) and the second gate electrode 152. The second gate electrode 152 may penetrate the source electrode 120 together with the insulating layer 151 and extend in the X direction. The second gate electrode 152 is insulated from the source electrode 120 by the insulating layer 151. The plurality of second gate electrodes 152 arranged (e.g., spaced apart) in the Z direction may be connected to, for example, a conductor 152a extending in the Z direction on the side of the source electrode 120. The conductor 152a may be electrically connected to, for example, the first gate electrode 160.

The second gate electrode 152 may include an electrode material. The electrode material may comprise, for example, a metal material or a conductive oxide. The metallic material may include, for example, Au, Ti, TiN, TaN, W, Mo, WN, Pt or Ni. The conductive oxide may include, for example, ITO, IZO, etc. The second gate electrode 152 may include the same material as the first gate electrode 160, the source electrode 120, and the drain electrode 130.

According to the field effect transistor 100a, each of the plurality of horizontal channels 141 is disposed between the first gate electrode 160 and the second gate electrode 152 to form a dual gating structure together with the first gate electrode 160 and the second gate electrode 152. Furthermore, each vertical channel 142 of the plurality of vertical channels 142 also forms the dual gating structure with the first gate electrode 160. Therefore, according to the field effect transistor 100a, a greater gating effect may be provided.

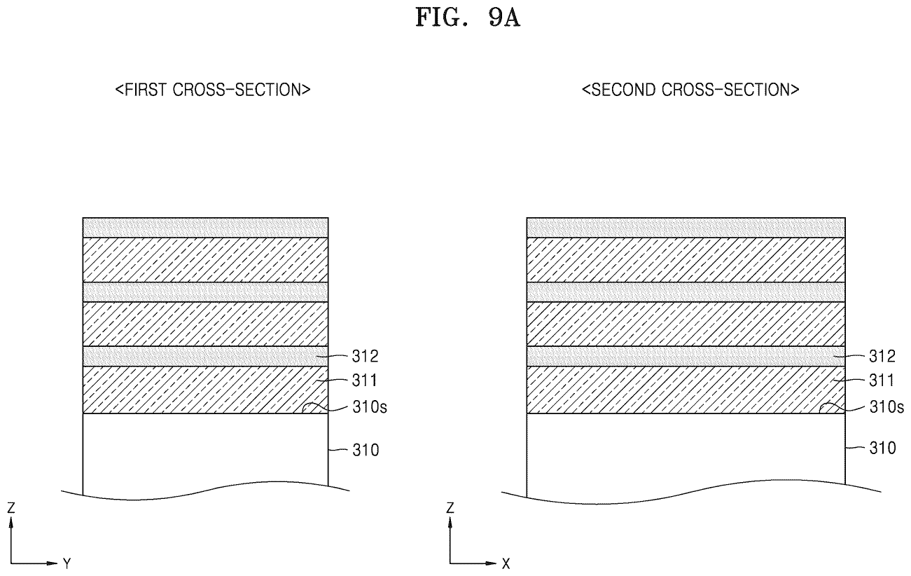

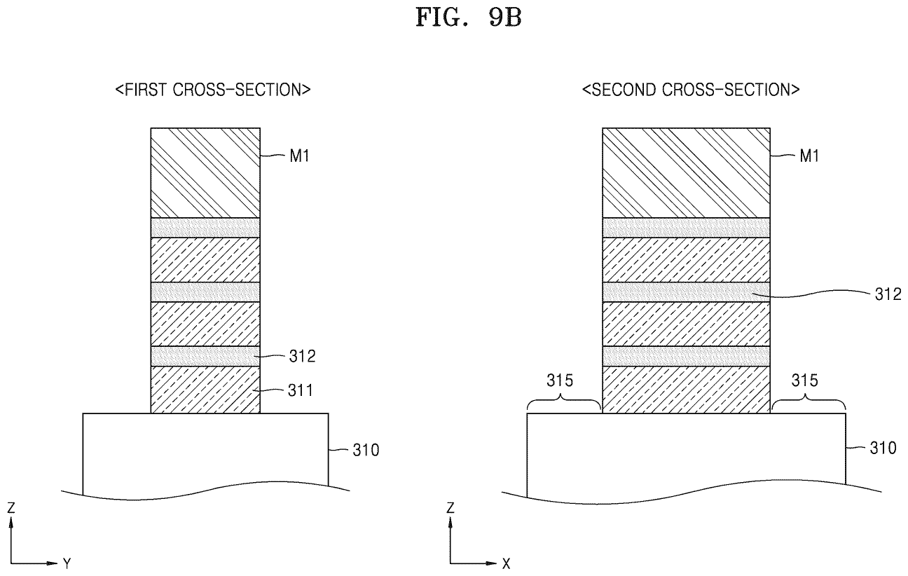

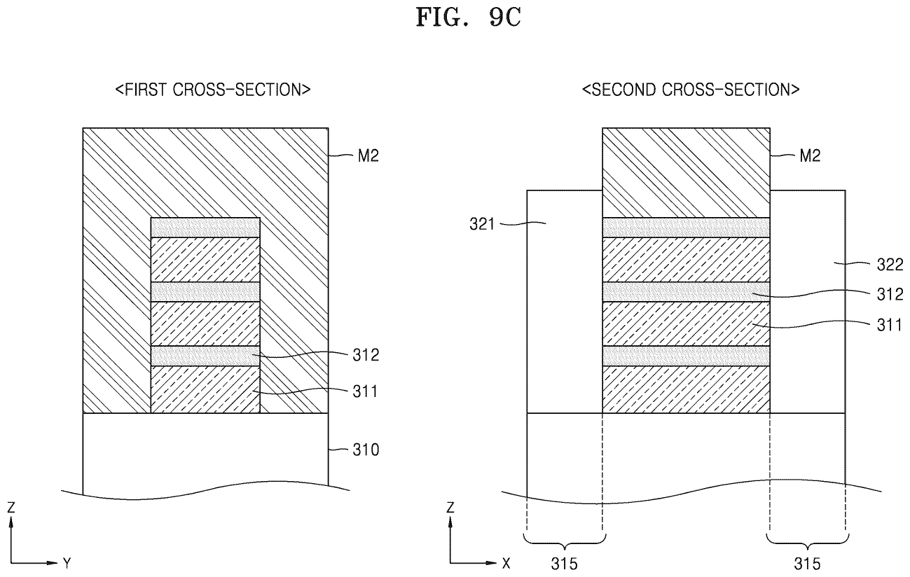

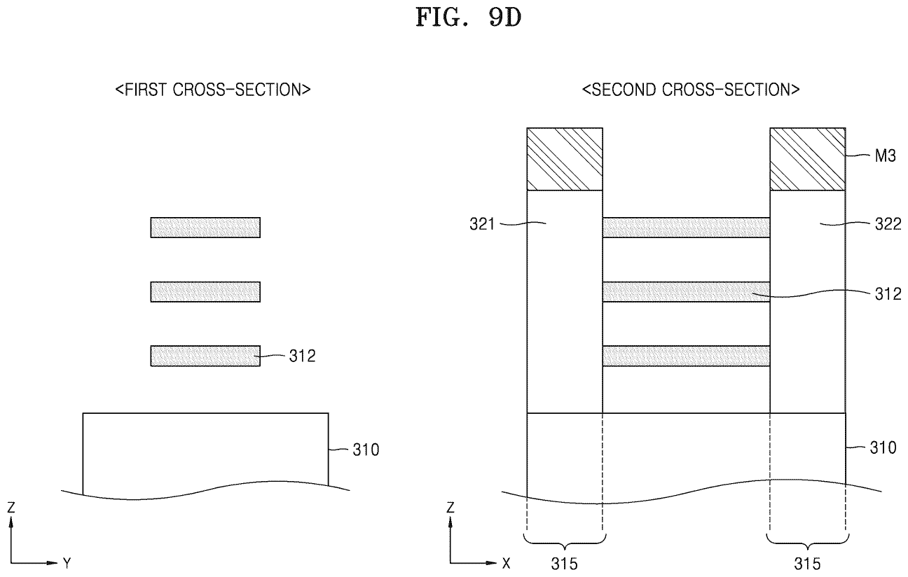

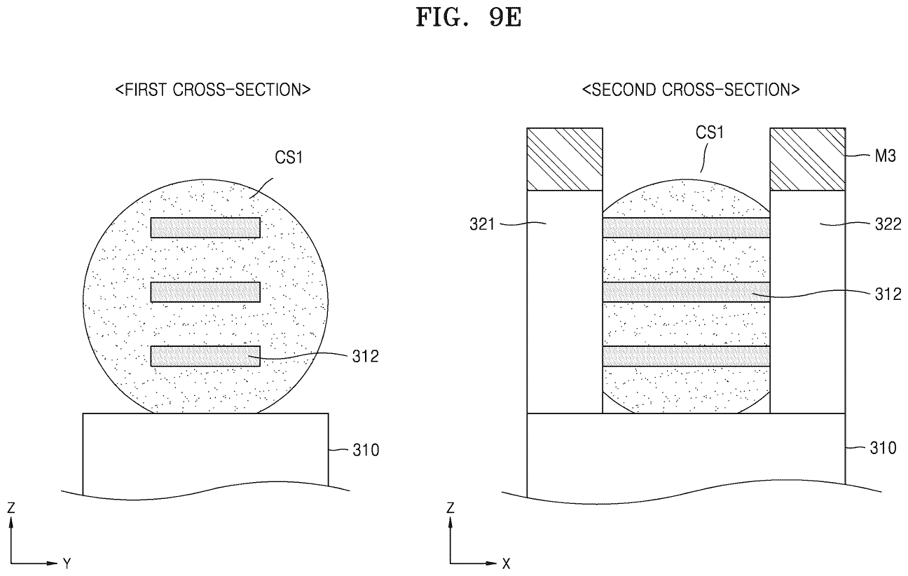

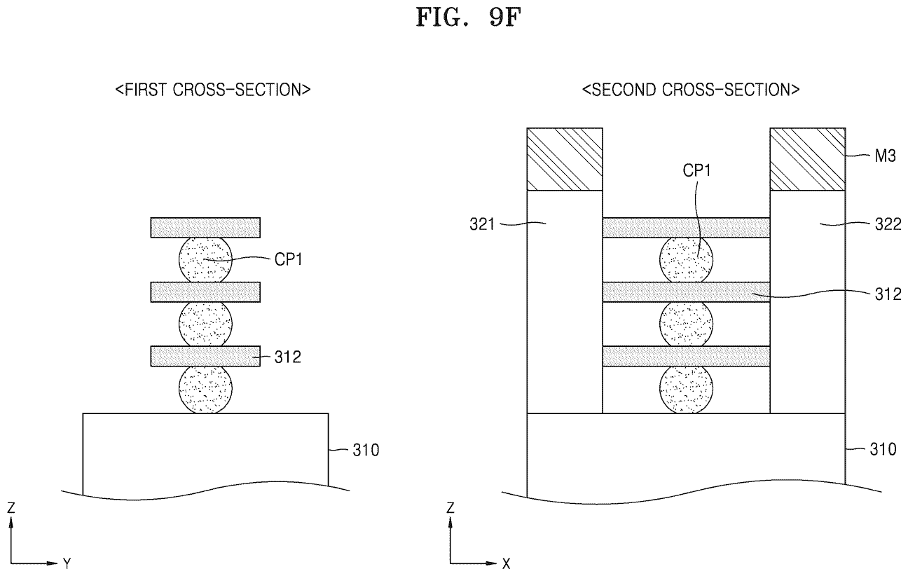

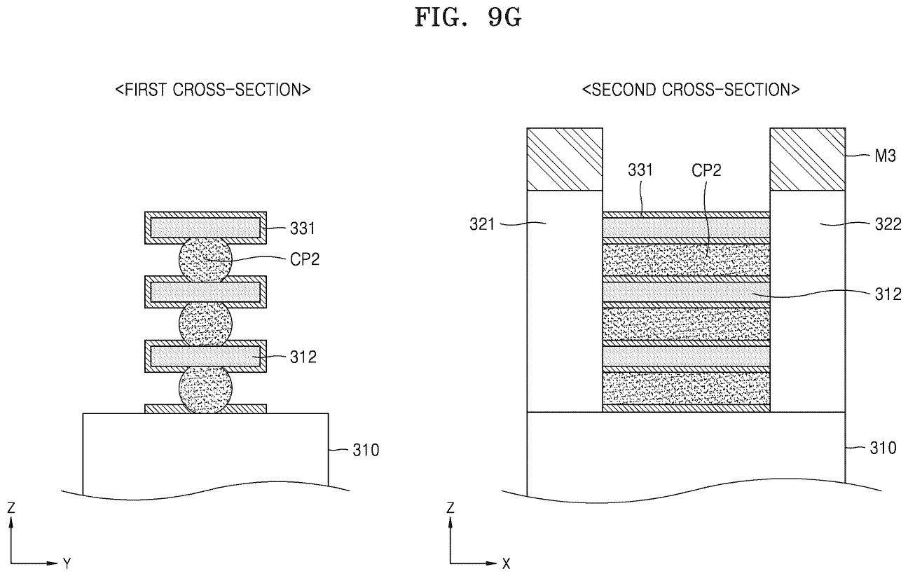

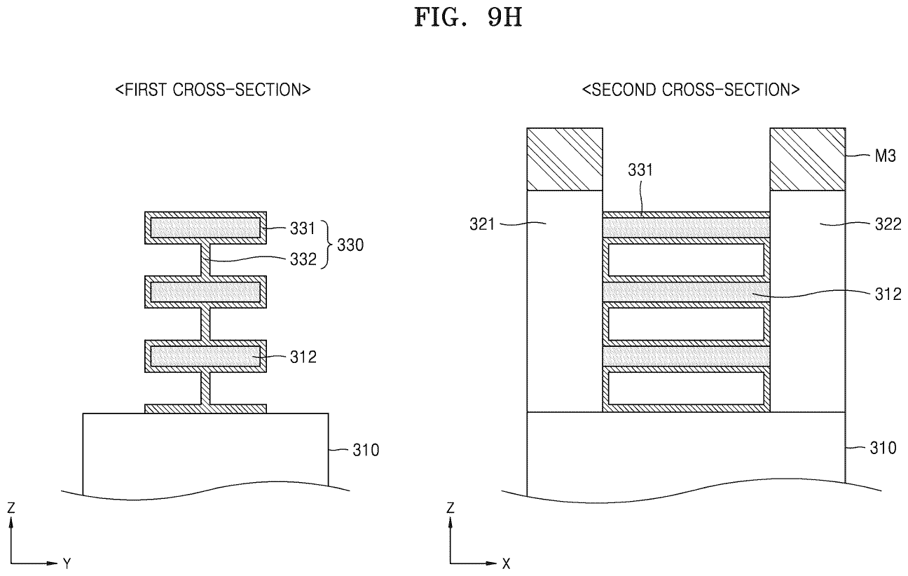

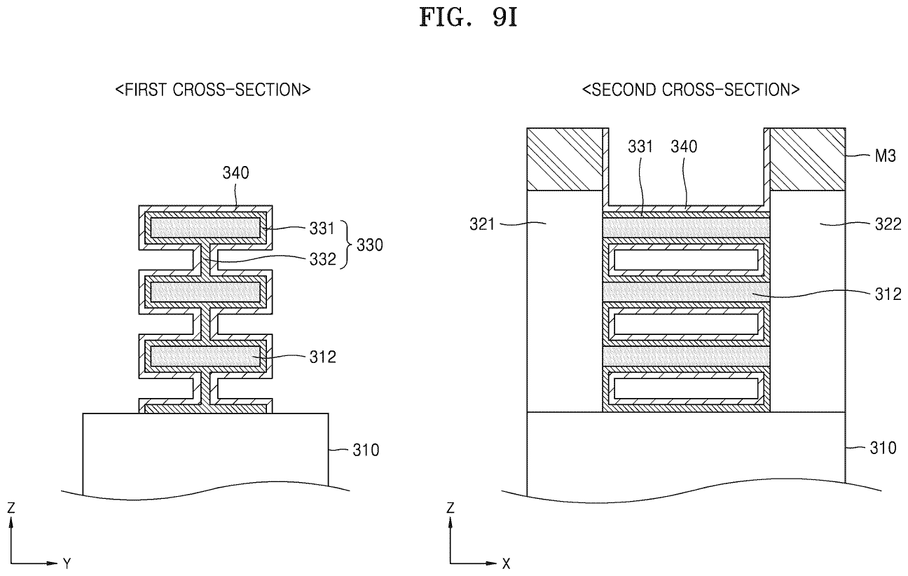

FIGS. 9A, 9B, 9C, 9D, 9E, 9F, 9G, 9H, 9I, and 9J are diagrams illustrating a method of manufacturing the field effect transistor 100 according to some example embodiments. To assist understanding, a first cross-section and a second cross-section are shown together in each of FIGS. 9A to 9J. Hereinafter, some example embodiments of the method of manufacturing the field effect transistor 100 will be described with reference to FIGS. 9A to 9J.

First, on a substrate, a source electrode, a drain electrode, and a plurality of bridges spaced apart in a direction perpendicular to the substrate (e.g., a direction extending perpendicular to an upper surface of the substrate) are formed between the source electrode and the drain electrode.

Referring to FIG. 9A, a sacrificial layer 311 and an insulating layer 312 are alternately stacked on a substrate 310 (e.g., on an upper surface 310s thereof). The substrate 310 may be an insulating substrate or a semiconductor substrate having an insulating layer formed on a surface thereof. The semiconductor substrate may include, for example, Si, Ge, SiGe, or a group III-V semiconductor material. The substrate 310 may be, for example, a silicon substrate in which a silicon oxide is formed on the surface thereof, but is not limited thereto. The sacrificial layer 311 may include materials that may be selectively removed according to an etching gas or an etching solution. The sacrificial layer 311 may include, for example, an inorganic material such as SiO₂, Al₂O₃, Si₃N₄, poly-Si, or SiGe, or an organic material such as PMMA or PR. The insulating layer 312 may include at least one of, for example, low-doped silicon, SiO₂, Al₂O₃, HfO₂, Si₃N₄, ZrO, HfZrO, or HfAlO.

Referring to FIG. 9B, a stack structure of the sacrificial layer 311 and the insulating layer 312 is patterned using a first mask M1. The first mask M1 may have a pattern corresponding to the source electrode and the drain electrode. The stack structure may be patterned by removing a partial region of the stack structure of the sacrificial layer 311 and the insulating layer 312 by using the first mask M1. In the second cross-section, electrode corresponding regions 315 may be formed on both sides of the patterned stack structure.

Referring to FIG. 9C, an electrode material is deposited, for example, in the electrode corresponding region 315 by using a second mask M2 to form a source electrode 321 and a drain electrode 322. The source electrode 321 and the drain electrode 322 are formed in the electrode corresponding region 315 on the substrate 310 in the second cross-section.

Referring to FIG. 9D, a third mask M3 is formed on the source electrode 321 and the drain electrode 322. The sacrificial layer 311 is removed by using the third mask M3 and an etching gas selectively etching only the sacrificial layer 311, and the plurality of insulating layers 312 remains. The plurality of insulating layers 312 may be positioned between the source electrode 321 and the drain electrode 322 to be spaced apart from each other in the Z direction in the form of a multi-bridge. The plurality of insulating layers 312 are connected to the source electrode 321 and the drain electrode 322. A plurality of bridges (multi-bridge structure) spaced apart from each other in a direction perpendicular to the substrate 310 (e.g., the Z direction, perpendicular to the upper surface 310s of the substrate 310) are implemented by the plurality of insulating layers 312.

Next, based on the multi-bridge structure, a channel including a plurality of horizontal channels on surfaces of the plurality of bridges and a vertical channel connecting two horizontal channels adjacent to each other in at least one of the plurality of horizontal channels is formed.

Referring to FIG. 9E, a catalyst solution CS1 is coated on the multi-bridge structure. A catalyst solution CS1 may include a catalyst which may include, for example, an alkali metal halide material such as NaCl, KI, or NaI, or a material including an alkali metal such as Na₂Mo₂O₇ or Na₂MoO₄. Accordingly, the catalyst solution CS1 may include catalyst particles which may include alkali metal such as particles of NaCl, KI, or NaI, or alkali metal such as Na₂Mo₂O₇ or Na₂MoO₄. A solvent may be, for example, water, an organic solvent such as ethanol, IPA, etc., or a mixture of two or more of these. A coating process may be performed, for example, by spin coating. A drying process is performed to partially remove the solvent. For example, a drying temperature may be 80° C., and a drying time may be 1 minute. Then, as shown in FIG. 9F, catalyst particles are gathered between the plurality of insulating layers 312 to form a catalyst particle layer CP1 connecting two insulating layers 312 adjacent to each other. The catalyst particle layer CP1 may partially include the solvent. As a result, catalyst particles may be supplied to the plurality of bridges implemented by the plurality of insulating layers 312, based on coating the catalyst solution CS1 on the multi-bridge structure and performing a drying process to at least partially remove the solvent from the catalyst solution CS1 (e.g., based on at least partially drying the catalyst solution CS1).

A stack structure including the substrate 310 shown in FIG. 9F is put (e.g., placed) into a deposition chamber for forming a channel by depositing a channel material, for example, a 2D semiconductor material. The channel may be formed through, for example, a chemical vapor deposition (CVD), a metal organic chemical vapor deposition (MOCVD), or an atomic layer deposition (ALD) process. In some example embodiments, the channel is formed through the CVD process.

When the internal temperature of the deposition chamber reaches a certain process temperature, for example, 600° C., a precursor of the channel material, that is, a precursor of the 2D semiconductor material, is supplied to the deposition chamber to be supplied to the plurality of bridges implemented by the plurality of insulating layers 312. The precursor of the 2D semiconductor material may include, for example, a transition metal precursor and a chalcogen element. The transition metal precursor reacts with catalyst particles to form, for example, a liquid intermediate CP2 such as Na₂Mo₂O₇ as shown in FIG. 9G. When a catalyst solution including Na₂Mo₂O₇ is coated, the liquid intermediate CP2 may be formed in an operation of heating to a process temperature in the deposition chamber. At the same time, the transition metal precursor and the chalcogen element react to deposit a TMD material (e.g., a channel material) on the surfaces of the plurality of insulating layers 312 so that a plurality of horizontal channels 331 begin to be formed. As a result, a plurality of horizontal channels 331 may be formed based on depositing the channel material on surfaces of the plurality of bridges (implemented by the plurality of insulating layers 312) from the precursor. The liquid intermediate CP2 also reacts with the chalcogen element so that the TMD material begins to be formed. After a certain processing time elapses, as shown in FIG. 9H, the TMD material is grown on the surfaces of the plurality of insulating layers 312 so that the formation of the plurality of horizontal channels 331 is completed, and the liquid intermediate CP2 is also exhausted so that a plurality of vertical channels 332 are formed. In the second cross-section of FIG. 9H, the vertical channel 332 is omitted. As a result, one or more vertical channels 332 connecting two horizontal channels 331 adjacent to each other in at least one vertical gap of a plurality of vertical gaps between adjacent horizontal channels of the plurality of horizontal channels may be formed based on reacting the catalyst particles of the liquid intermediate CP2 with the precursor of the channel material supplied to the plurality of bridges implemented by the plurality of insulating layers 312. Accordingly, a channel 330 that includes the plurality of horizontal channels 331 and one or more vertical channels 332 may be formed.

Accordingly, the plurality of horizontal channels 331 in a closed-loop shape may be formed in the first cross-section and the second cross-section. When a channel 330 includes a 2D material, it is difficult to form the channel 330 because the thickness of the channel 330 is very thin, but in some example embodiments, the insulating layer 312 serves to support the channel 330, and thus, the channel 330 may be easily formed by thinly depositing the 2D material.

In addition, the plurality of vertical channels 332 do not penetrate the plurality of horizontal channels 331. The plurality of vertical channels 332 do not penetrate the plurality of insulating layers 312, that is, a plurality of bridges. Therefore, the plurality of horizontal channels 331 and the plurality of vertical channels 332 may include the same material in the same process. The plurality of horizontal channels 331 and the plurality of vertical channels 332 may be defined by separate portions of a single, unitary piece of material (e.g., channel material). The number of processes and the process time may be reduced compared to a comparative process including forming a through hole penetrating a plurality of horizontal channels and a plurality of insulating layers after forming the plurality of horizontal channels and filling the through hole with a channel material to form a plurality of vertical channels. In addition, a horizontal channel and a vertical channel are formed with the same material in a single process, and thus crystal structure of the horizontal channel and the vertical channel is continuous. Accordingly, the quality of the channel including the horizontal channel and the vertical channel may be improved, thereby enabling the resultant field effect transistor that includes the channel 330 having the horizontal channels 331 and the one or more vertical channels 332 to have improved performance and/or improved power consumption efficiency.

Next, a gate insulating layer 340 may be formed as shown in FIG. 9I by depositing a dielectric material on the horizontal channel 331 and the vertical channel 332 in the state shown in FIG. 9H. The gate insulating layer 340 may be formed using a CVD method, an MOCVD method, or an ALD method.

Next, as shown in FIG. 9J, an electrode material is deposited on the gate insulating layer 340 to form a gate electrode 350, and the third mask M3 is removed.

The method of manufacturing the field effect transistor described with reference to FIGS. 9A to 9J uses a gate last process in which the gate electrode 350 is formed later than the source electrode 321 and the drain electrode 322. In some example embodiments, the plurality of insulating layers 312 may be formed between the source electrode 321 and the drain electrode 322, and the plurality of horizontal channels 331 and the plurality of vertical channels 332 may be easily formed based on the plurality of insulating layers 312.

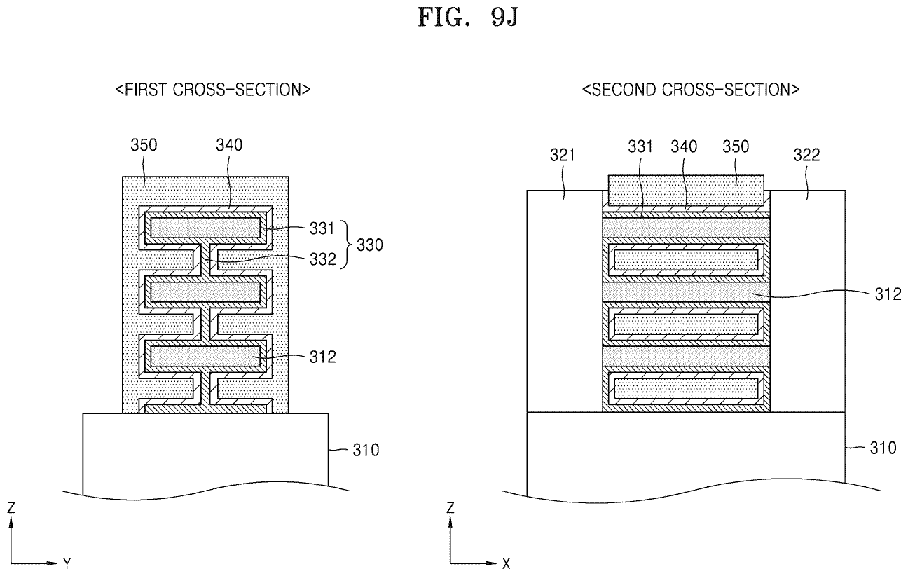

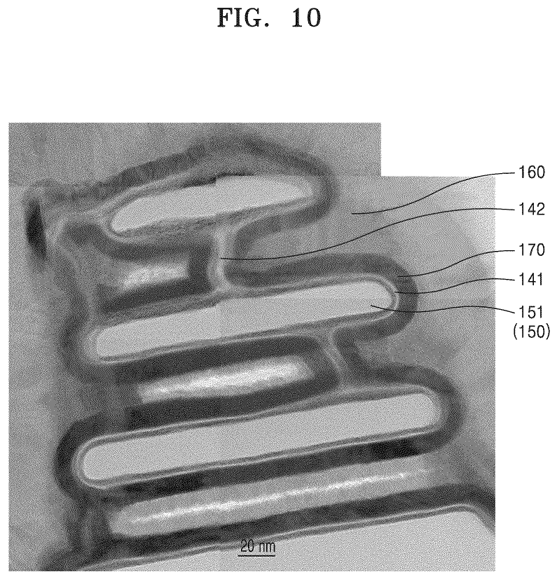

FIG. 10 illustrates a transmission electron microscopy (TEM) image obtained by forming a vertical channel connecting two horizontal channels adjacent to each other between a plurality of horizontal channels through a MOCVD method. In FIG. 10, it is confirmed that one or more TMD material layers are formed in a connection portion where the horizontal channels and the vertical channel are connected to each other.

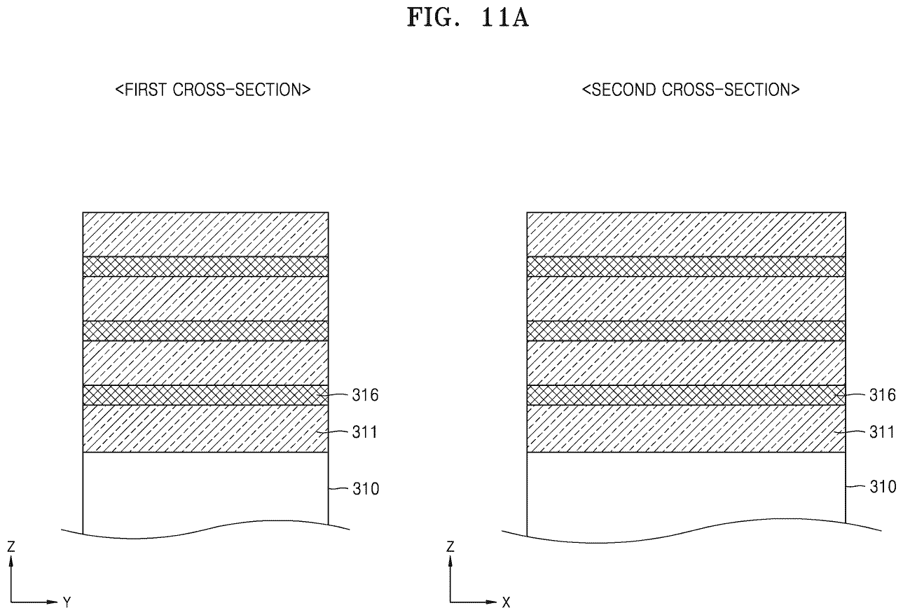

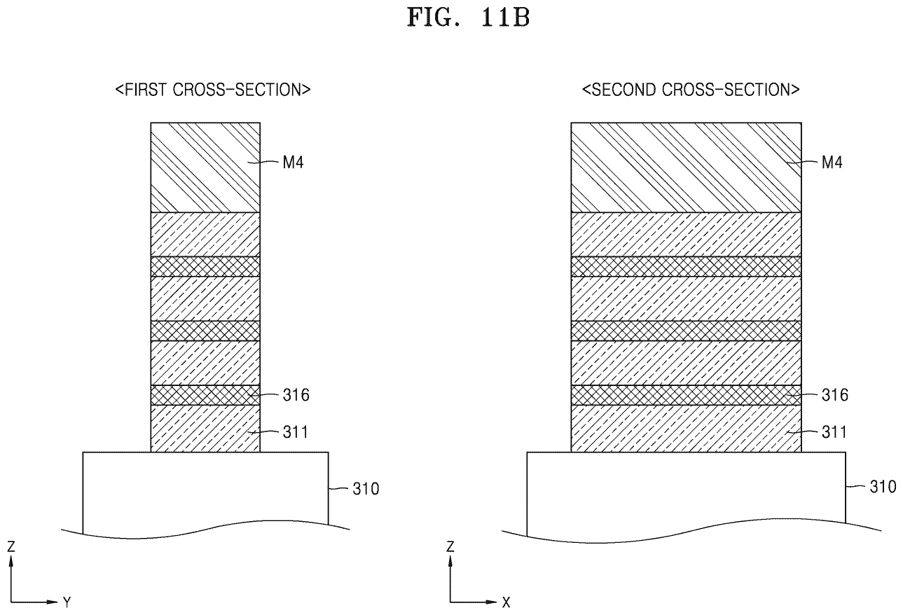

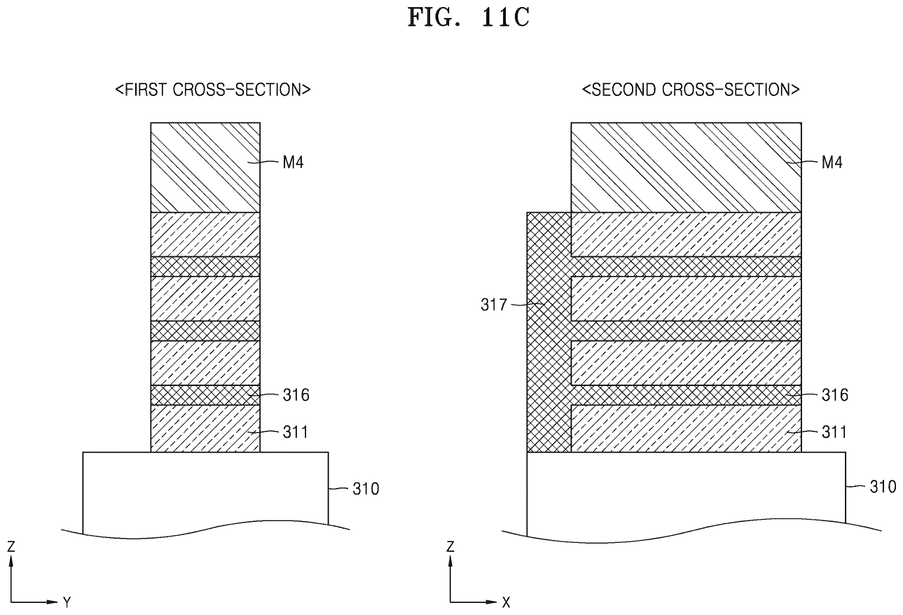

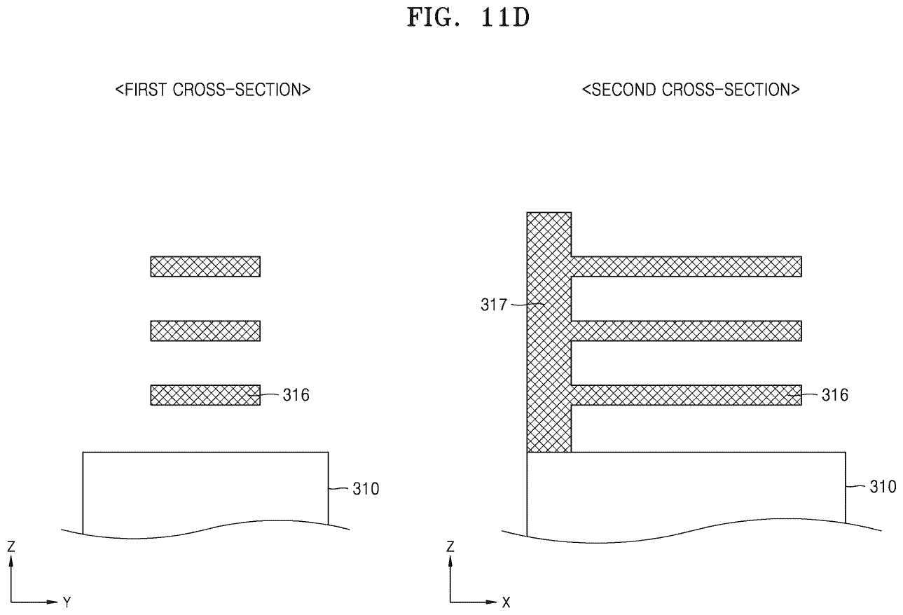

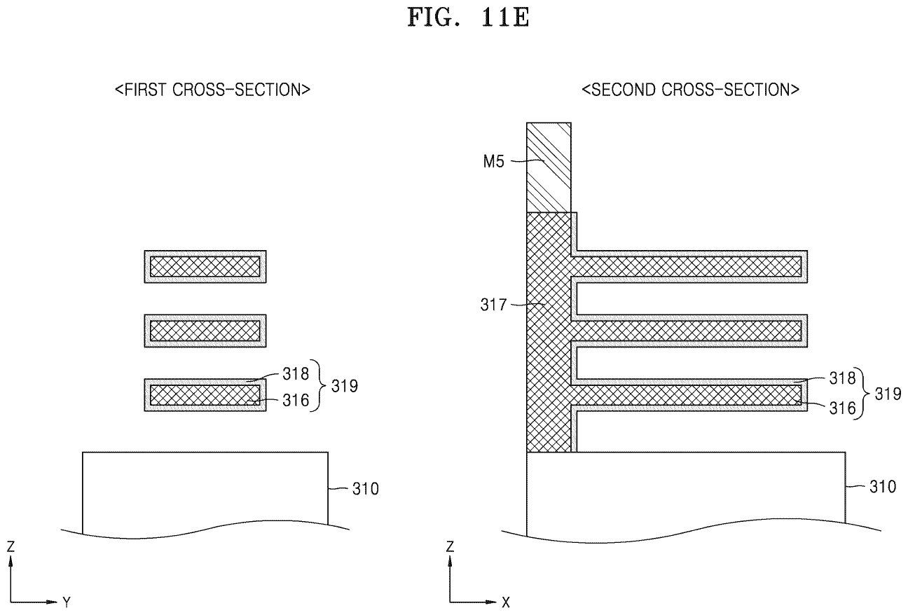

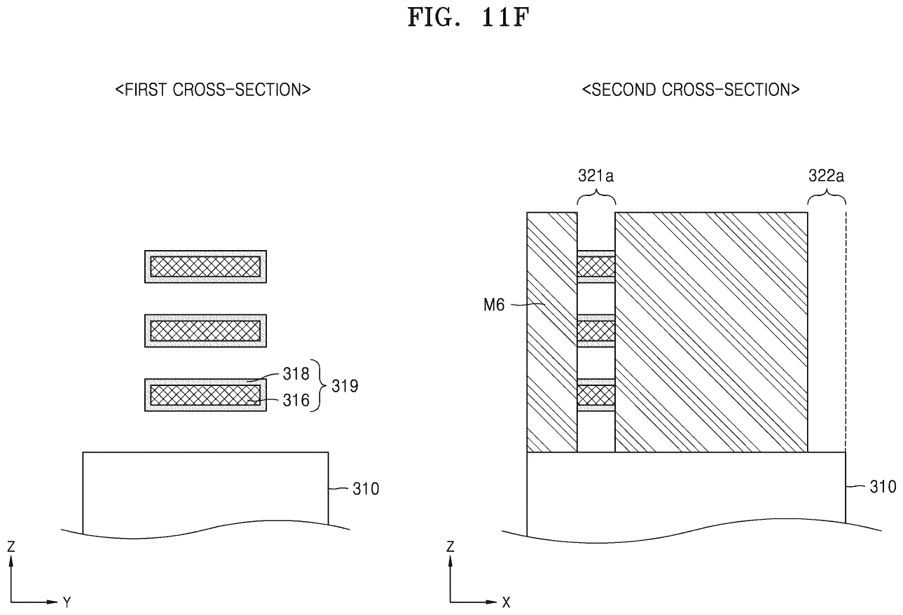

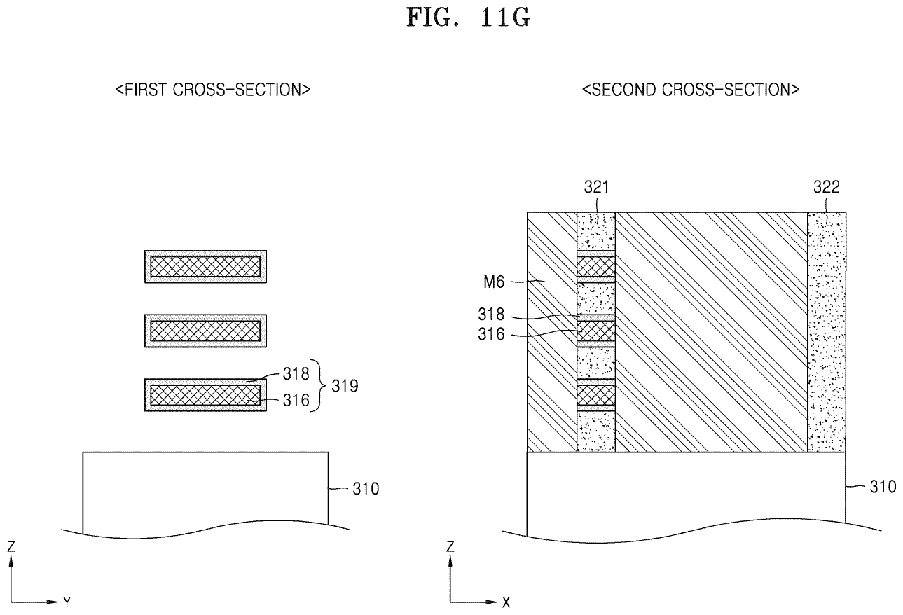

FIGS. 11A, 11B, 11C, 11D, 11E, 11F, 11G, and 11H are diagrams illustrating a method of manufacturing the field effect transistor 100a according to some example embodiments. To assist understanding, a first cross-section and a second cross-section are shown together in each of FIGS. 11A to 11H.

First, a plurality of bridges, including a source electrode, a drain electrode, and a second gate electrode spaced apart in a direction perpendicular to a substrate between the source electrode and the drain electrode, are formed on the substrate.

Referring to FIG. 11A, the sacrificial layer 311 and a conductive layer 316 are alternately stacked on the substrate 310. The substrate 310 may be an insulating substrate or a semiconductor substrate having an insulating layer formed on a surface thereof. The semiconductor substrate may include, for example, Si, Ge, SiGe, or a group III-V semiconductor material. The substrate 310 may be, for example, a silicon substrate in which a silicon oxide is formed on the surface thereof, but is not limited thereto. The sacrificial layer 311 may include materials that may be selectively removed according to an etching gas or an etching solution. The sacrificial layer 311 may include, for example, an inorganic material such as SiO₂, Al₂O₃, Si₃N₄, poly-Si, or SiGe, or an organic material such as PMMA or PR. The conductive layer 316 may include an electrode material. The electrode material may comprise, for example, a metal material or a conductive oxide. The metallic material may include, for example, Au, Ti, TiN, TaN, W, Mo, WN, Pt or Ni. The conductive oxide may include, for example, ITO, IZO, etc.

Referring to FIG. 11B, a partial region of a stack structure of the sacrificial layer 311 and the conductive layer 316 may be removed using a mask M4. The mask M4 may have a pattern corresponding to the conductor 152a and the drain electrode 130 described above.

Referring to FIG. 11C, a conductor 317 is formed by depositing, for example, an electrode material on one side of a stack structure of the sacrificial layer 311 and the conductive layer 316 by using the mask M4. The conductor 317 may be connected to one end of the conductive layers 316 in the X direction and may extend in the Z direction.

Referring to FIG. 11D, the sacrificial layer 311 is removed by using an etching gas selectively etching only the sacrificial layer 311, and the mask M4 is removed so that the plurality of conductive layers 316 remain. The plurality of conductive layers 316 extend in the X direction and are positioned to be spaced apart from each other in the Z direction.

Referring to FIG. 11E, an insulating layer 318 is formed by depositing an insulating material on a surface of the conductor 317 by using a mask M5. The insulating material may include at least one of, for example, low-doped silicon, SiO₂, Al₂O₃, HfO₂, Si₃N₄, ZrO, HfZrO, or HfAlO. The insulating layer 318 may surround the conductive layer 316 in the first cross-section. In the second cross-section, the insulating layer 318 may be formed on the surfaces of the plurality of conductive layers 316 and a surface of the conductor 317 to which the plurality of conductive layers 316 are connected.

Referring to FIG. 11F, a mask M6 is formed. The mask M6 defines a region 321a in which a source electrode is to be formed and a region 322a in which a drain electrode is to be formed. As shown in FIG. 11G, the source electrode 321 and the drain electrode 322 are formed by, for example, depositing an electrode material in the regions 321a and 322a defined by the mask M6. Then, when the mask M6 is removed, a plurality of bridges 319, i.e. a multi-bridge structure, including the conductive layer 316 buried in the insulating layer 318 and spaced apart from each other in the Z direction may be formed between the source electrode 321 and the drain electrode 322 spaced apart from each other in the X direction as shown in FIG. 11H.

Next, based on the multi-bridge structure, a channel including a plurality of horizontal channels on surfaces of the plurality of bridges and a vertical channel connecting two horizontal channels adjacent to each other in at least one of the plurality of horizontal channels is formed. FIG. 11H corresponds to FIG. 9D among FIGS. 9A to 9J illustrating the embodiments of the method of manufacturing the field effect transistor 100 described above. Therefore, the field effect transistor 100a shown in FIGS. 7 and 8 may be manufactured by performing the process described with reference to FIGS. 9E to 9J in the state shown in FIG. 11H.

The field effect transistor according to some example embodiments includes horizontal channels in the form of a multi-bridge and a vertical channel connecting the horizontal channels, thereby suppressing a short channel effect, effectively reducing the thickness and length of the channel, and simultaneously improving gate controllability. The method of manufacturing the field effect transistor according to some example embodiments may easily form a very thin channel of several nm or less. The field effect transistor according to some example embodiments has an ultra-small size and excellent electrical performance, and thus is suitable for application to an integrated circuit device having a high degree of integration. The field effect transistor according to some example embodiments may form the vertical channel in the same process as horizontal channels, thereby forming the horizontal channels and the vertical channel of excellent quality.

The field effect transistor according to some example embodiments may be configured as a transistor including a digital circuit or an analog circuit. In some embodiments, the field effect transistor may be used as a high voltage transistor or a low voltage transistor. For example, the field effect transistor of some example embodiments may be configured as a high voltage transistor that constitutes a peripheral circuit of a flash memory device which is a nonvolatile memory device that operates at a high voltage or an electrically operable and programmable read only memory (EEPROM) device. In some example embodiments, the field effect transistor of some example embodiments may be configured as a transistor including an IC device for a liquid crystal display (LCD) that requires an operating voltage of 10 V or more, for example, about 20 V to about 30 V, or an IC chip used in a plasma display panel (PDP) that requires an operating voltage of 100 V.

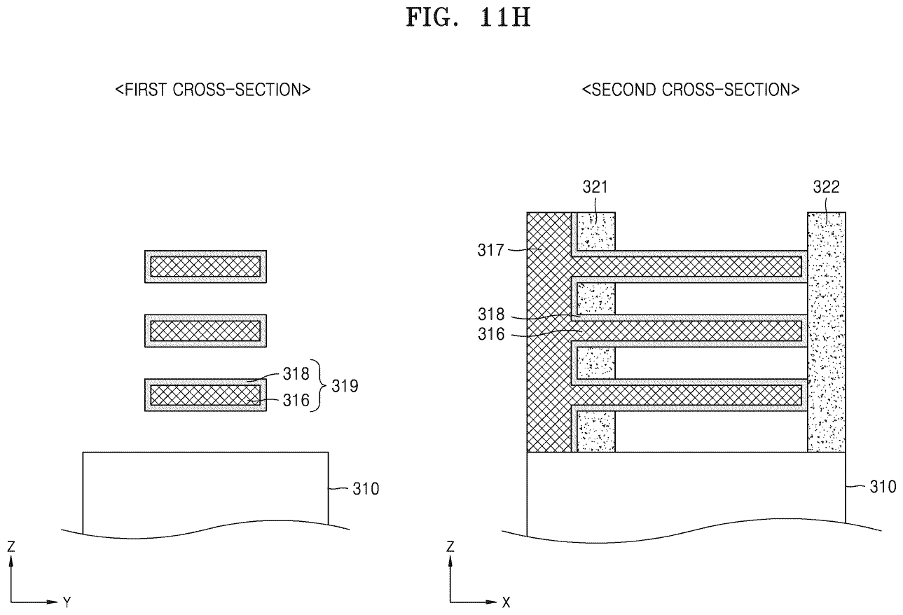

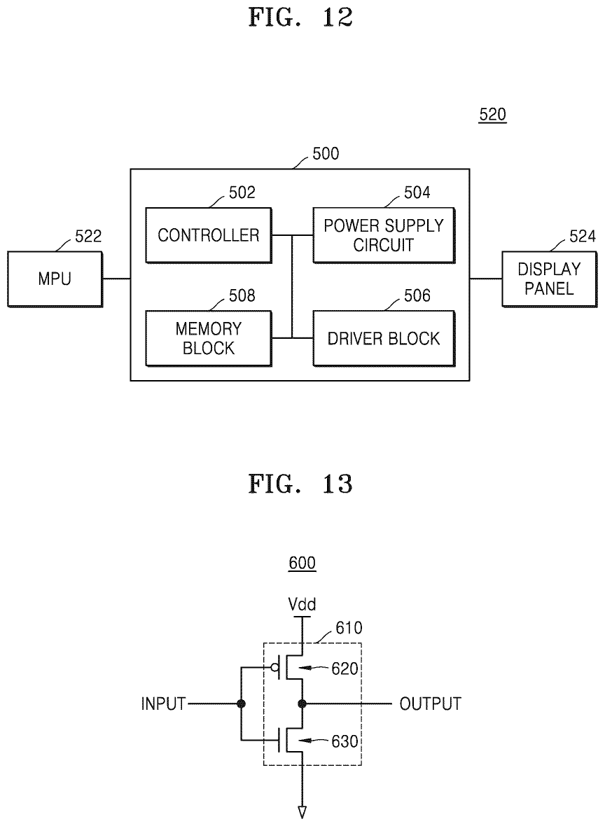

FIG. 12 is a schematic block diagram of a display driver IC (DDI) 500 and a display device 520 including the DDI 500 according to some example embodiments.

Referring to FIG. 12, the DDI 500 may include a controller 502, a power supply circuit 504, a driver block 506, and a memory block 508. The controller 502 may receive and decode commands issued from a main processing unit (MPU) 522, and control each block of the DDI 500 to implement operations according to the commands. The power supply circuit 504 generates a driving voltage in response to the control of the controller 502. The driver block 506 drives a display panel 524 by using the driving voltage generated by the power supply circuit 504 in response to the control of the controller 502. The display panel 524 may be a liquid crystal display panel or a plasma display panel. The memory block 508 is a block that temporarily stores commands input to the controller 502 or control signals output from the controller 502, or stores necessary data, and may include memory such as RAM or ROM. The power supply circuit 504 and the driver block 506 may each include the field effect transistors 100 and 100a according to the embodiments described above with reference to FIGS. 1 to 3, 7, and 8.

FIG. 13 is a circuit diagram of a complementary metal oxide semiconductor (CMOS) inverter 600 according to some example embodiments. The CMOS inverter 600 includes a CMOS transistor 610. The CMOS transistor 610 includes a PMOS transistor 620 and an NMOS transistor 630 connected between a power terminal Vdd and a ground terminal. The CMOS transistor 610 may include the field effect transistors 100 and 100a according to the embodiments described above with reference to FIGS. 1 to 3, 7, and 8.

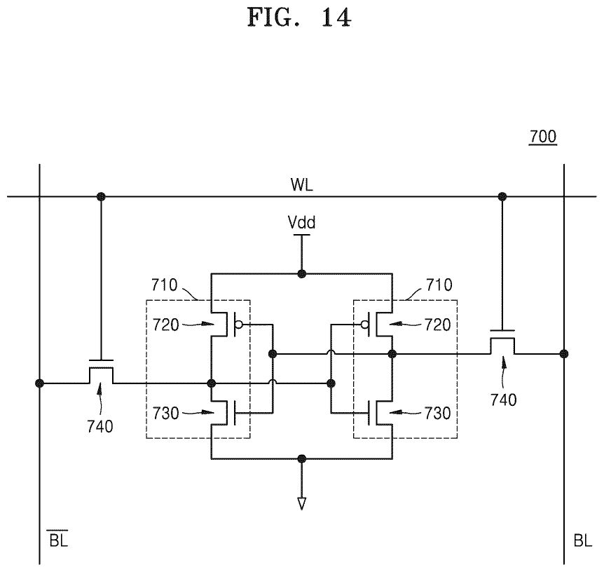

FIG. 14 is a circuit diagram of a CMOS static random-access memory (SRAM) device 700 according to some example embodiments. Referring to FIG. 14, the CMOS SRAM device 700 includes a pair of driving transistors 710. The pair of driving transistors 710 each includes a PMOS transistor 720 and an NMOS transistor 730 connected between the power terminal Vdd and a ground terminal. The CMOS SRAM device 700 may further include a pair of transfer transistors 740. Sources of the transfer transistors 740 are cross-connected to a common node of the PMOS transistors 720 and the NMOS transistors 730 included in the driving transistors 710. The power terminal Vdd is connected to a source of the PMOS transistor 720, and the ground terminal is connected to a source of the NMOS transistor 730. A word line WL may be connected to a gate of the pair of transfer transistors 740, and a bit line BL and an inverted bit line may be respectively connected to drains of the pair of transfer transistors 740. At least one of the driving transistors 710 and the transfer transistors 740 of the CMOS SRAM device 700 may include the field effect transistors 100 and 100a according to the embodiments described above with reference to FIGS. 1 to 3, 7, and 8.

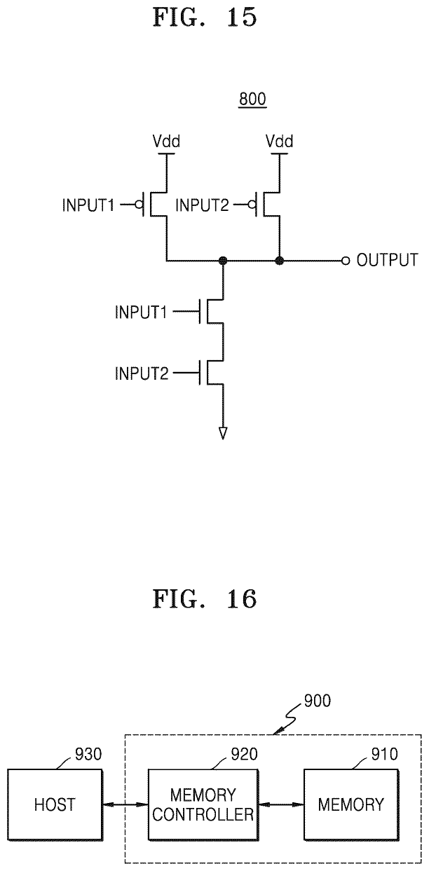

FIG. 15 is a circuit diagram of a CMOS NAND circuit 800 according to some example embodiments. Referring to FIG. 15, the CMOS NAND circuit 800 includes a pair of CMOS transistors through which different input signals are transmitted. The NAND circuit 800 may include the field effect transistors 100 and 100a according to the embodiments described above with reference to FIGS. 1 to 3, 7, and 8.

FIG. 16 is a block diagram illustrating an electronic system 900 according to some example embodiments. Referring to FIG. 16, the electronic system 900 includes a memory 910 and a memory controller 920. The memory controller 920 may control the memory 910 to read data from and/or write data to the memory 910 in response to a request from a host 930. At least one of the memory 910 and the memory controller 920 may include the field effect transistors 100 and 100a according to the embodiments described above with reference to FIGS. 1 to 3, 7, and 8.

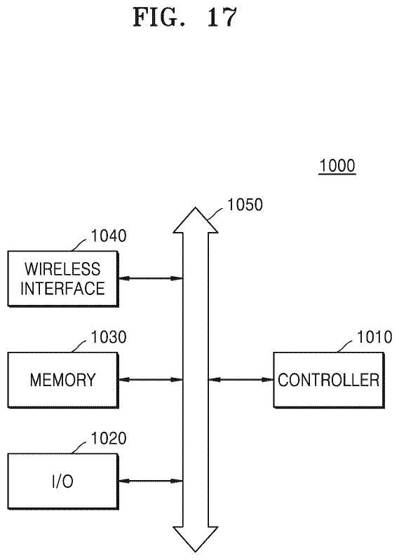

FIG. 17 is a block diagram of an electronic system 1000 according to some example embodiments. Referring to FIG. 17, the electronic system 1000 may configure a wireless communication device, or a device capable of transmitting and/or receiving information in a wireless environment. The electronic system 1000 includes a controller 1010, an input/output device (I/O) 1020, a memory 1030, and a wireless interface 1040, which are interconnected via a bus 1050.

The controller 1010 may include at least one of a microprocessor, a digital signal processor, or a processing device similar to these. The input/output device 1020 may include at least one of a keypad, a keyboard, or a display. The memory 1030 may be used to store commands executed by controller 1010. For example, the memory 1030 may be used to store user data. The electronic system 1000 may use the wireless interface 1040 to transmit/receive data over a wireless communication network. The wireless interface 1040 may include an antenna and/or a wireless transceiver. In some embodiments, the electronic system 1000 may be used in a communication interface protocol of a third generation communication system, such as code division multiple access (CDMA), global system for mobile communications (GSM), north American digital cellular (NADC), extended-time division multiple access (E-TDMA), and/or wide band code division multiple access (WCDMA). The electronic system 1000 may include the field effect transistors 100 and 100a according to some example embodiments, including the example embodiments described above with reference to FIGS. 1 to 3, 7, and 8.

As described herein, any devices, systems, modules, portions, units, controllers, circuits, and/or portions thereof according to any of the example embodiments, and/or any portions thereof (including, without limitation, the DDI 500, the controller 502, the power supply circuit 504, the driver block 506, the memory block 508, the display device 520, the MPU 522, the display panel 524, the electronic system 900, the memory 910, the memory controller 920, the electronic system 1000, the controller 1010, the input/output interface 1020, the memory 1030, the wireless interface 1040, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

The field effect transistor according to some example embodiments may exhibit good electrical performance with an ultra-small structure, and thus may be applied to an integrated circuit device, and may implement miniaturization, low power, and high performance.

According to some example embodiments, the field effect transistor includes the plurality of horizontal channels and at least one vertical channel, and thus a facing area between the channel and the gate electrode may be increased, and the field effect transistor having improved gate controllability may be implemented.

According to some example embodiments, the plurality of horizontal channels and at least one vertical channel include the same material, and thus the field effect transistor having a stable channel may be implemented.

It should be understood that example embodiments described herein should be considered in a descriptive sense only and not for purposes of limitation. Descriptions of features or aspects within each example embodiment should typically be considered as available for other similar features or aspects in some example embodiments. While some example embodiments have been described with reference to the figures, it will be understood by those of ordinary skill in the art that various changes in form and details may be made therein without departing from the spirit and scope as defined by the following claims.

What is claimed is:

1. A field effect transistor, comprising:
a source electrode and a drain electrode on a substrate, the source electrode and the drain electrode spaced apart from each other in a first direction parallel to an upper surface of the substrate;
a plurality of horizontal channels between the source electrode and the drain electrode, the plurality of horizontal channels spaced apart from each other in a second direction perpendicular to the upper surface of the substrate;
a vertical channel in at least one vertical gap defined between two horizontal channels of the plurality of horizontal channels adjacent to each other in the second direction, such that the vertical channel connects the two horizontal channels to each other in the second direction, the vertical channel extending in the first direction between the source electrode and the drain electrode;
a first gate electrode facing the plurality of horizontal channels and the vertical channel; and
a gate insulating layer insulating the first gate electrode from each of the source electrode, the drain electrode, the plurality of horizontal channels, and the vertical channel,
wherein the plurality of horizontal channels and the vertical channel each independently include a two-dimensional (2D) semiconductor material.

2. The field effect transistor of claim 1, wherein the vertical channel does not penetrate the plurality of horizontal channels.

3. The field effect transistor of claim 1, wherein in a cross-section perpendicular to the first direction, the first gate electrode at least partially surrounds the plurality of horizontal channels and the vertical channel.

4. The field effect transistor of claim 1, further comprising:
a plurality of bridges supported by the source electrode and the drain electrode and spaced apart from each other in the second direction,
wherein in a cross-section perpendicular to the first direction, the plurality of horizontal channels include a horizontal channel in a closed-loop shape surrounding a separate bridge of the plurality of bridges.

5. The field effect transistor of claim 4, wherein each bridge of the plurality of bridges includes an insulating layer.

6. The field effect transistor of claim 5, wherein the insulating layer includes at least one of low-doped silicon, SiO₂, Al₂O₃, HfO₂, Si₃N₄, ZrO, HfZrO, or HfAlO.

7. The field effect transistor of claim 4, wherein each bridge of the plurality of bridges includes
a second gate electrode; and
an insulating layer surrounding the second gate electrode, the insulating layer between the plurality of horizontal channels and the second gate electrode.

8. The field effect transistor of claim 4, wherein the vertical channel does not penetrate the plurality of bridges.

9. The field effect transistor of claim 1, wherein the plurality of horizontal channels and the vertical channel include a same material.

10. The field effect transistor of claim 1, wherein the 2D semiconductor material has a multilayer structure.

11. The field effect transistor of claim 1, wherein the 2D semiconductor material includes graphene, black phosphorus, phosphorene, or transition metal dichalcogenide (TMD).

12. The field effect transistor of claim 11, wherein the TMD includes
one metal element selected from the group consisting of Mo, W, Nb, V, Ta, Ti, Zr, Hf, Tc, Re, Cu, Ga, In, Sn, Ge, and Pb, and
one chalcogen element selected from the group consisting of S, Se, and Te.

13. The field effect transistor of claim 11, wherein the 2D semiconductor material is doped with a particular conductive dopant.

14. A method of manufacturing a field effect transistor, the method comprising:
forming, on a substrate, a source electrode, a drain electrode, and a plurality of bridges, the plurality of bridges spaced apart from each other in a direction perpendicular to an upper surface of the substrate, the plurality of bridges between the source electrode and the drain electrode;
forming a channel based on
supplying catalyst particles and a precursor of a channel material to the plurality of bridges,
forming a plurality of horizontal channels based on depositing the channel material on surfaces of the plurality of bridges from the precursor, and
forming a vertical channel connecting two horizontal channels adjacent to each other in at least one vertical gap of a plurality of vertical gaps between adjacent horizontal channels of the plurality of horizontal channels based on reacting the catalyst particles with the precursor of the channel material;
depositing a gate insulating layer on the channel; and
depositing a gate electrode on the gate insulating layer.

15. The method of claim 14, wherein the forming of the channel includes
forming a catalyst particle layer including the catalyst particles between adjacent bridges of the plurality of bridges; and
placing a stack structure including the substrate into a deposition chamber and supplying the precursor of the channel material.

16. The method of claim 15, wherein the forming of the catalyst particle layer includes
coating a catalyst solution including the catalyst particles on the plurality of bridges; and
at least partially drying the catalyst solution.

17. The method of claim 15, wherein the forming of the channel further includes
forming a liquid intermediate based on reacting the precursor of the channel material with the catalyst particles, and
forming the vertical channel from the liquid intermediate.

18. The method of claim 14, wherein the channel material includes a transition metal dichalcogenide (TMD).

19. The method of claim 18, wherein the catalyst particles include NaCl, KI, or NaI.

20. The method of claim 18, wherein the catalyst particles include Na₂Mo₂O₇ or Na₂MoO₄.
